(19) United States
(12) Patent Application Publication
(10) Pub. No.: US 2012/0049829 A1
(43) Pub. Date: Mar. 1, 2012

(54) Power Supply Apparatus and Electronic Device Provided With Same

(75) Inventor: Kazuhiro Murakami, Kyoto (JP)

(73) Assignee: ROHM CO., LTD., Kyoto (JP)

(21) Appl. No.: 13/265,033

(22) PCT Filed: May 18, 2010
(86) PCT No.: PCT/JP2010/058346

§ 371 Date: Oct. 18, 2011

(30) Foreign Application Priority Data
May 19, 2009 (JP) 2009-120491
May 19, 2009 (JP) 2009-120501
Dec. 9, 2009 (JP) 2009-279416

(51) Int. Cl. G05F 1/00; H02H 3/08; H03L 5/00; G05F 1/10

(52) U.S. Cl. 323/288; 323/282; 327/543; 361/86; 327/333

(57) ABSTRACT

A power supply apparatus A according to the present invention comprises a drive control circuit for generating an on/off control signal of an output transistor; an overcurrent protection circuit for directly or indirectly monitoring a coil current and generating an overcurrent detection signal; and a soft-start control circuit for suppressing a rise in an output voltage by using a soft-start voltage for starting an increase slowly after startup of the power supply apparatus, wherein, when the coil current is in an overcurrent state, the drive control circuit repeats a forced reset operation of the on/off control signal in accordance with the overcurrent detection signal, and a set operation of the on/off control signal in accordance with a clock signal of a predetermined frequency, as a pulse-by-pulse overcurrent protection operation; and the soft-start control circuit gradually reduces the soft-start voltage as a reset operation in accordance with the overcurrent detection signal.

### TECHNICAL FIELD

The present invention relates to a power supply apparatus provided with an overcurrent protection function, and to an electronic device which is provided with the power supply apparatus.

### BACKGROUND ART

### First Prior Art Example

FIG. 7 is a circuit block diagram showing a first prior art example of a power supply apparatus. This prior art example is a switching regulator for generating a desired output voltage Vout from an input voltage Vin by driving the switching of an output transistor 201, and as output feedback control means for the output transistor 201, has an error amplifier 202, a pulse width modulation (PWM) comparator 203, and a drive control circuit 204. Although not shown in FIG. 7, a coil, diode, capacitor, and other components forming a step-up, step-down, or step-up/step-down output stage are connected to the output transistor 201.

The error amplifier 202 amplifies the difference between a predetermined target voltage Vtg and a feedback voltage Vfb which corresponds to the output voltage Vout, and generates an error voltage Vern The PWM comparator 203 compares the error voltage Verr and a triangular-wave slope voltage Vslope, thereby generates a pulse width modulation signal PWM for determining a switching duty, and transmits the pulse width modulation signal PWM to the drive control circuit 204. The drive control circuit 204 generates an on/off control signal of the output transistor 201 on the basis of a clock signal CLK and the pulse width modulation signal PWM. More specifically, the drive control circuit 204 sets the on/off control signal of the output transistor 201 to high level using the rising edge of the clock signal CLK as a trigger, and sets the on/off control signal of the output transistor 201 to low level using the rising edge of the pulse width modulation signal PWM as a trigger.

The power supply apparatus of this prior art example has an overcurrent protection circuit 205 and a logical sum operator 206 as overcurrent protection means for the coil current IL that flows to a coil (not shown) connected to the output transistor 201.

When the coil current IL is detected as having reached a predetermined overcurrent detection value Iocp, the overcurrent protection circuit 205 raises an overcurrent detection signal OCP from low level (normal logical level) to high level (abnormal logical level). The logical sum operator 206 substitutes the logical sum signal of the pulse width modulation signal PWM and the overcurrent detection signal OCP with the pulse width modulation signal PWM and feeds the pulse width modulation signal PWM to the drive control circuit 204.

Consequently, when the coil current IL attains an overcurrent state and the overcurrent detection signal OCP is raised to high level (abnormal logical level), the drive control circuit 204 resets the on/off control signal of the output transistor 201 to low level irrespective of the pulse width modulation signal PWM. As a result, the output transistor 201 is forced off, and the coil current IL is blocked.

When the coil current IL is blocked by the overcurrent protection operation described above, since the overcurrent detection signal OCP falls back to low level (normal logical level), when the clock signal CLK subsequently rises to high level, the drive control circuit 204 sets the on/off control signal of the output transistor 201 back to high level, and the output transistor 201 is again switched on. However, when the overcurrent state of the coil current IL is not cancelled at that time, the same overcurrent protection operation as described above is commenced, and the output transistor 201 is therefore forced off and the coil current IL is again blocked.

In the power supply apparatus according to the first prior art example, a so-called pulse-by-pulse mode is employed in which a forced reset operation by the overcurrent detection signal OCP and a set operation (self-resetting operation) by the clock signal CLK are repeated as the overcurrent protection operation for the coil current IL.

FIG. 8 is a waveform diagram showing the overcurrent protection operation of the first prior art example, and shows, in order from the top, the coil current IL, the overcurrent detection signal OCP, and the error voltage Verr.

### Second Prior Art Example

FIG. 9 is a circuit block diagram showing a second prior art example of the power supply apparatus. The power supply apparatus of this prior art example is basically the same as that of the preceding first prior art example, but differs in that the subject of resetting by the overcurrent detection signal OCP is a soft-start circuit 207 rather than the drive control circuit 204.

The soft-start circuit 207 initiates startup of the power supply apparatus as well as charging of a capacitor 207a, and controls the degree of conduction of a transistor 207d, thereby clamping the error voltage Verr to an upper limit value which corresponds to a predetermined soft-start voltage Vss (charging voltage of the capacitor 207a). By such soft-start control, the output voltage Vout can be raised slowly. When the error voltage Verr has decreased below the soft-start voltage Vss, the transistor 207d is placed in a non-operating state, and soft-start control is therefore ended.

On the other hand, when the coil current IL attains an overcurrent state and the overcurrent detection signal OCP is raised to high level (abnormal logical level), since a transistor 207c is switched on, the charge accumulated in the capacitor 207a is immediately discharged. As a result, since the transistor 207d is placed in a full-on state and the error voltage Verr is reduced to a zero value, the on-duty of the pulse width modulation signal PWM attains a zero value, the output transistor 201 is forced off, and the coil current IL is blocked.

When the coil current IL is blocked by the overcurrent protection operation described above, since the overcurrent detection signal OCP again falls to low level (normal logical level), the transistor 207c is switched off, and charging of the capacitor 207a is again initiated. Consequently, the same soft-start control is performed during resetting from the overcurrent protection operation as during startup of the power supply apparatus.

A so-called soft-start reset mode is thus employed as the overcurrent protection operation for the coil current IL in the power supply apparatus according to the second prior art example.

FIG. 10 is a waveform diagram showing the overcurrent protection operation of the second prior art example, and shows the behavior of the coil current IL.

Patent Citation 1 and Patent Citation 2 may be cited as examples of conventional techniques relating to the above.

Patent Citation 3 may be cited as an example of a through-current prevention technique for a level shifter circuit.

### LIST OF CITATIONS

### Patent Literature

Patent Citation 1: Japanese Laid-open Patent Publication No. 2000-166227
Patent Citation 2: Japanese Laid-open Patent Publication No. 2008-187847
Patent Citation 3: Japanese Laid-open Patent Publication No. 6-204850

### SUMMARY OF INVENTION

### Technical Problem

In the power supply apparatus of the first prior art example described above, since the output transistor 201 can be immediately switched off when the coil current IL reaches the predetermined overcurrent detection value Iocp, the coil current IL does not exceed the overcurrent detection value Iocp, and high overcurrent-suppressing effects are certainly achievable.

However, the power supply apparatus of the first prior art example is configured so that while the coil current IL is in the overcurrent state, the drive control circuit 204 is reset by the overcurrent detection signal OCP, and the output transistor 201 is forced off, whereas output feedback operation is continued without any resetting of the error amplifier 202. Therefore, in the case that the output voltage Vout is significantly below the target value thereof at the time that the overcurrent state of the coil current IL is cancelled, since the on-duty of the pulse width modulation signal PWM is determined based on an extremely high error voltage Verr, there is a risk of overshoot of the output voltage Vout when the switching operation of the output transistor 201 is returned.

On the other hand, in the power supply apparatus of the second prior art example, since the soft-start circuit 207 is reset when the coil current IL reaches the predetermined overcurrent detection value Iocp, and the same soft-start control is performed as during startup of the power supply apparatus at the return from the overcurrent protection operation, there is no risk of overshoot of the output voltage Vout.

However, in the power supply apparatus of the second prior art example, according to the reset speed (discharge speed of the capacitor 207a) of the soft-start circuit 207 or a phase compensation capacitor (not shown in FIG. 9) connected to the output terminal of the error amplifier 202, there is a risk of the coil current IL exceeding the predetermined overcurrent detection value Iocp (see FIG. 10).

The power supply apparatus of the second prior art example is configured so that the charge accumulated in the capacitor 207a is immediately discharged when the coil current IL reaches the predetermined overcurrent detection value Iocp. Therefore, during the return from the overcurrent protection operation, soft-start control always starts over from the beginning, and the output voltage Vout decreases significantly. There is therefore a risk of malfunction, depending upon the application for which the power supply apparatus is mounted.

In view of the problems described above as discovered by the present inventors, an object of the present invention is to provide a power supply apparatus capable both of reliably suppressing overcurrent and preventing overshoot during return, and to provide an electronic device provided with the power supply apparatus.

### Solution to Problem

In order to achieve the abovementioned objects, the power supply apparatus according to the present invention (first aspect) is a power supply apparatus for generating a desired output voltage from an input voltage by switching an output transistor on and off and driving a coil current; the power supply apparatus comprising a drive control circuit for generating an on/off control signal of the output transistor; an overcurrent protection circuit for directly or indirectly monitoring the coil current and generating an overcurrent detection signal; and a soft-start control circuit for suppressing a rise in the output voltage by using a soft-start voltage for starting an increase slowly after startup of the power supply apparatus; wherein, when the coil current is in an overcurrent state, the drive control circuit repeats a forced reset operation of the on/off control signal in accordance with the overcurrent detection signal, and a set operation of the on/off control signal in accordance with a clock signal of a predetermined frequency, as a pulse-by-pulse overcurrent protection operation; and the soft-start control circuit gradually reduces the soft-start voltage as a reset operation in accordance with the overcurrent detection signal.

In the power supply apparatus according to the first aspect described above, a configuration (second aspect) may be adopted in which the soft-start control circuit has a capacitor; a first constant-current source for generating a charging current for the capacitor; and a second constant-current source for generating a discharge current for the capacitor in accordance with the overcurrent detection signal; and the ratio of the charging current and the discharge current is set so that during a reset operation in accordance with the overcurrent detection signal, not all of the charge accumulated in the capacitor is immediately discharged, and the soft-start voltage is incrementally reduced while the overcurrent protection operation of a pulse-by-pulse mode is being performed.

The power supply apparatus according to the second aspect described above may further comprise (third aspect) an error amplifier for amplifying the difference between a predetermined target voltage and a feedback voltage which corresponds to the output voltage and generating an error voltage; an oscillator for generating the clock signal and transmitting the clock signal as a setting signal of the drive control circuit; a slope voltage generation circuit for generating a slope voltage having a triangular waveform, a ramp waveform, or a sawtooth waveform on the basis of the clock signal; and a PWM comparator for comparing the error voltage and the slope voltage to generate a pulse width modulation signal, and transmitting the pulse width modulation signal as a reset signal of the drive control circuit.

The power supply apparatus according to the third aspect described above may comprise (fourth aspect) a clamp circuit for clamping the error voltage to an upper limit value which corresponds to the soft-start voltage.

In the power supply apparatus according to the third aspect described above, a configuration (fifth aspect) may be adopted in which the error amplifier amplifies the difference between the target voltage and the lower of the feedback voltage and the soft-start voltage and generates the error voltage.

An electronic device according to the present invention comprises (sixth aspect) the power supply apparatus configured according to any of the first through fifth aspects described above.

The electronic device according to the sixth aspect described above may comprise (seventh aspect) a port to which is mounted a bus power device which operates upon receiving a power feed from the power supply apparatus.

The power supply apparatus according to the first aspect described above may further comprise (eighth aspect) a level shifter circuit inserted between the drive control circuit and the output transistor.

In the power supply apparatus according to the eighth aspect described above, a configuration (ninth aspect) may be adopted in which the level shifter circuit takes as input an input signal which is pulse-driven between a first power supply potential and a ground potential, converts the input signal to an output signal which is pulse-driven between the ground potential and a second power supply potential higher than the first power supply potential, and outputs the output signal; and has first and second P-channel field-effect transistors, each of the sources thereof connected to an application terminal for the second power supply potential; first and second N-channel field-effect transistors, each of the sources thereof being connected to a ground terminal, and each of the gates thereof connected to an input terminal for the input signal and a logically inverted signal thereof; a first resistor, one end thereof being connected to the drain of the first P-channel field-effect transistor and another end being connected to the gate of the second P-channel field-effect transistor and the drain of the first N-channel field-effect transistor; and a second resistor, one end thereof being connected to the drain of the second P-channel field-effect transistor and another end being connected to the gate of the first P-channel field-effect transistor, the drain of the second N-channel field-effect transistor, and an output terminal of said output signal.

In the power supply apparatus according to the eighth aspect described above, a configuration (tenth aspect) may be adopted in which the level shifter circuit takes as input an input signal which is pulse-driven between a second power supply potential and a ground potential, converts the input signal to an output signal which is pulse-driven between the ground potential and a first power supply potential lower than the second power supply potential, and outputs the output signal; and has first and second N-channel field-effect transistors, each of the sources thereof being connected to ground terminal; first and second P-channel field-effect transistors, each of the sources thereof being connected to an application terminal for the first power supply potential, and each of the gates thereof being connected to an input terminal for the input signal and a logically inverted signal thereof; a first resistor, one end thereof being connected to the drain of the first N-channel field-effect transistor and another end being connected to the gate of the second N-channel field-effect transistor and the drain of the first P-channel field-effect transistor; and a second resistor, one end thereof being connected to the drain of the second N-channel field-effect transistor and another end being connected to the gate of the first N-channel field-effect transistor, the drain of the second P-channel field-effect transistor, and an output terminal of said output signal.

The threshold voltage generation circuit according to the present invention may be configured (eleventh aspect) so as to be integrated in a semiconductor apparatus and to divert a specific external terminal, to which a high-input-impedance element is externally attached, for use as an external terminal for externally attaching a resistor for setting a threshold voltage; cause a predetermined constant voltage to occur in said specific external terminal by supplying a predetermined constant current to said specific external terminal prior to the start of normal operation of said semiconductor apparatus; and store the constant voltage as the threshold voltage.

The threshold voltage generation circuit according to the eleventh aspect described above may comprise (twelfth aspect) a constant-current source for supplying the constant current to the specific external terminal a clock generation unit for generating a clock signal; a counter for counting the number of pulses of the clock signal and outputting the count value as a digital signal; a digital/analog converter for converting the digital signal to analog and generating a sweep voltage in which the voltage value increases in accordance with counting up performed by the counter; and a comparator for comparing the sweep voltage and the constant voltage and generating a control signal for suspending normal operation of the semiconductor apparatus and causing the constant-current source and the clock generation unit to operate until the sweep voltage reaches the constant voltage, then stopping the constant-current source and the clock generation unit and initiating normal operation of the semiconductor apparatus once said sweep voltage has reached the constant voltage; wherein the sweep voltage is outputted as the threshold voltage.

In the threshold voltage generation circuit according to the twelfth aspect described above, a configuration (thirteenth aspect) may be adopted in which operation of the constant-current source and the clock generation unit is initiated when an under-voltage protection operation of the semiconductor apparatus is cancelled.

In the threshold voltage generation circuit according to any of the eleventh through thirteenth aspects described above, a configuration (fourteenth aspect) may be adopted in which a pull-up resistor or pull-down resistor externally attached to the specific external terminal is diverted for use as the resistor for setting the threshold voltage.

An overcurrent protection circuit according to the present invention comprises (fifteenth aspect) the threshold voltage generation circuit according to any of the eleventh through fourteenth aspects described above; and an overcurrent protection signal generation circuit for comparing the threshold voltage and a pulsed switch voltage which is drawn from one end of a switch element externally attached to the semiconductor apparatus, and generating an overcurrent protection signal.

In the overcurrent protection circuit according to the fifteenth aspect described above, a configuration (sixteenth aspect) may be adopted in which the high-input-impedance element is a field-effect transistor used as the switch element.

A switch drive apparatus according to the present invention comprises (seventeenth aspect) a control circuit for controlling the driving of the switch element; a drive circuit for generating a drive signal of the switch element on the basis of an instruction of the control circuit; and the overcurrent protection circuit according to the fifteenth or sixteenth aspect described above; the switch drive apparatus characterized in that at least one of the control circuit and the drive circuit stops the driving of the switch element when a switch current flowing to the switch element is recognized as being in an overcurrent state on the basis of the overcurrent protection signal.

A power supply apparatus according to the present invention comprises (eighteenth aspect) the switch drive apparatus according to the seventeenth aspect described above; the switch element, switched on and off by the switch drive apparatus; and a smoothing circuit for smoothing the switch voltage and generating an output voltage.

A level shifter circuit according to the present invention is (nineteenth aspect) a level shifter circuit for taking as input an input signal which is pulse-driven between a first power supply potential and a ground potential, converting the input signal to an output signal which is pulse-driven between the ground potential and a second power supply potential higher than the first power supply potential, and outputting the output signal; the level shifter circuit comprising first and second P-channel field-effect transistors, each of the sources thereof being connected to an application terminal for the second power supply potential; first and second N-channel field-effect transistors, each of the sources thereof being connected to a ground terminal, and each of the gates thereof being connected to an input terminal for the input signal and a logically inverted signal thereof; a first resistor, one end thereof being connected to the drain of the first P-channel field-effect transistor and another end being connected to the gate of the second P-channel field-effect transistor and the drain of the first N-channel field-effect transistor; and a second resistor, one end thereof being connected to the drain of the second P-channel field-effect transistor and another end being connected to the gate of the first P-channel field-effect transistor, the drain of the second N-channel field-effect transistor, and an output terminal of said output signal.

A level shifter circuit according to the present invention (twentieth aspect) is a level shifter circuit for taking as input an input signal which is pulse-driven between a second power supply potential and a ground potential, converting the input signal to an output signal which is pulse-driven between the ground potential and a first power supply potential lower than the second power supply potential, and outputting the output signal; the level shifter circuit comprising first and second N-channel field-effect transistors, each of the sources thereof being connected to ground terminal; first and second P-channel field-effect transistors, each of the sources thereof being connected to an application terminal for the first power supply potential, and each of the gates thereof being connected to an input terminal for the input signal and a logically inverted signal thereof; a first resistor, one end thereof being connected to the drain of the first N-channel field-effect transistor and another end being connected to the gate of the second N-channel field-effect transistor and the drain of the first P-channel field-effect transistor; and a second resistor, one end thereof being connected to the drain of the second N-channel field-effect transistor and another end being connected to the gate of the first N-channel field-effect transistor, the drain of the second P-channel field-effect transistor, and an output terminal of said output signal.

### Effect of the Invention

Through the power supply apparatus and the electronic device provided with the power supply apparatus according to the present invention, it is possible both to reliably suppress overcurrent and to prevent overshoot during return.

### BRIEF DESCRIPTION OF DRAWINGS

FIG. 1 is a block diagram showing an example of the configuration of an electronic device provided with the power supply apparatus according to the present invention;

FIG. 2 is a circuit block diagram showing an example of the configuration of the power supply apparatus A;

FIG. 3 is a circuit block diagram showing an example of the configuration of the overcurrent protection circuit 17;

FIG. 4 is a circuit block diagram showing a first configuration example of the drive control circuit 4 and the soft-start control circuit 6;

FIG. 5 is a waveform diagram showing the overcurrent protection operation;

FIG. 6 is a circuit block diagram showing a second configuration example of the soft-start control circuit 6;

FIG. 7 is a circuit block diagram showing a first prior art example of the power supply apparatus;

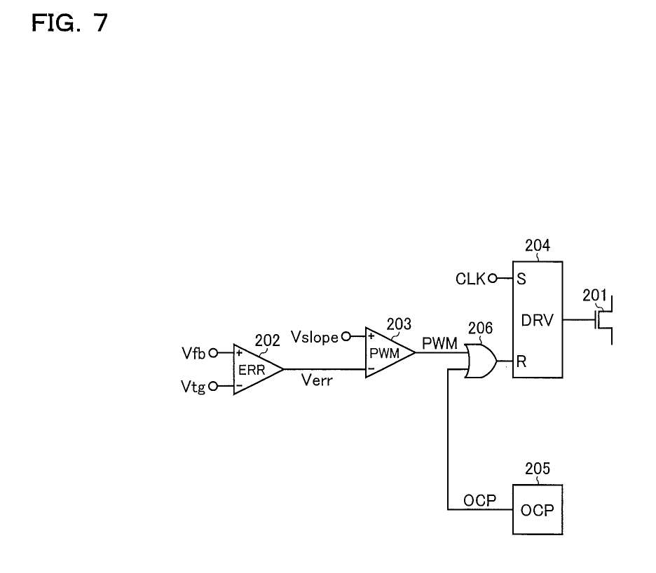

FIG. 8 is a waveform diagram showing the overcurrent protection operation of the first prior art example;

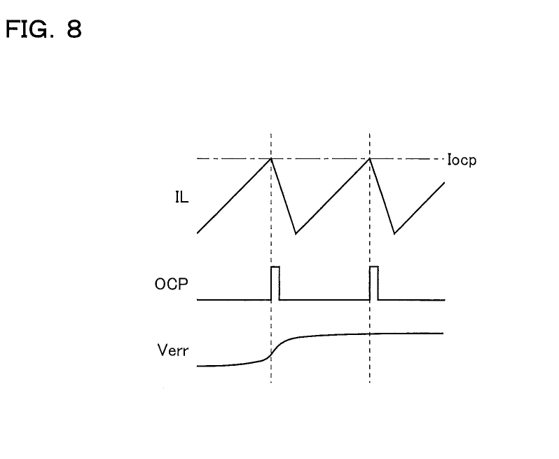

FIG. 9 is a circuit block diagram showing a second prior art example of the power supply apparatus;

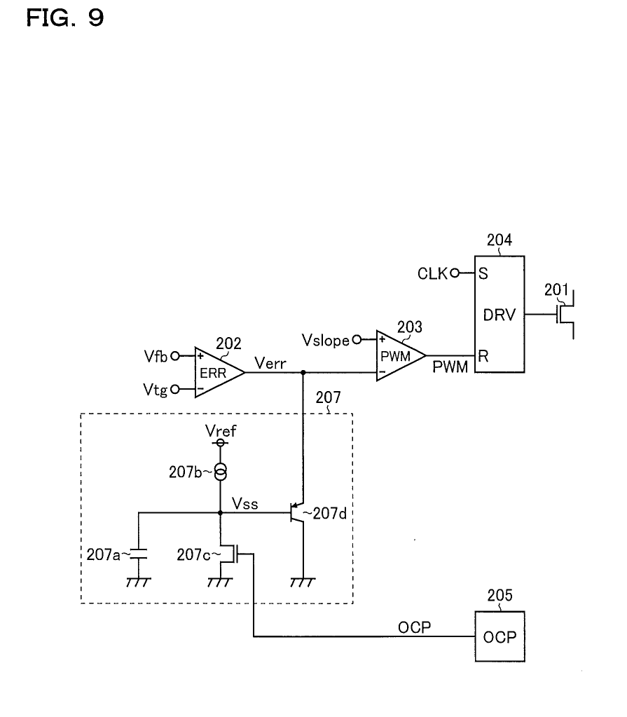

FIG. 10 is a waveform diagram showing the overcurrent protection operation of the second prior art example;

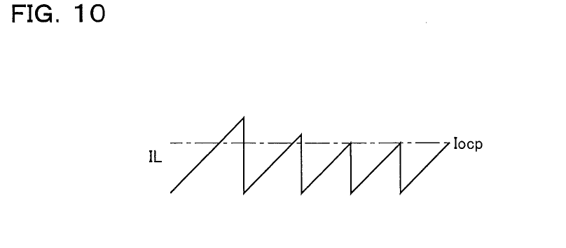

FIG. 11 is a circuit diagram showing a first embodiment of the level shifter circuit according to the present invention;

FIG. 12 is a circuit diagram showing a second embodiment of the level shifter circuit according to the present invention;

FIG. 13 is a circuit diagram showing a prior art example of a level shifter circuit;

FIG. 14 is a view showing an embodiment of the power supply apparatus which uses the threshold voltage generation circuit according to the present invention;

FIG. 15 is a circuit diagram showing an example of the configuration of the control circuit Y10 and the drive circuit Y20;

FIG. 16 is a timing chart showing an example of the operation of the control circuit Y10 and the drive circuit Y20;

FIG. 17 is a timing chart showing the setting operation for the threshold voltage Vth;

FIG. 18 is a timing chart showing an example of the overcurrent protection operation; and

FIG. 19 is a circuit diagram showing a prior art example of the overcurrent protection circuit.

### DESCRIPTION OF EMBODIMENTS

<First Technical Characteristic>

A first technical characteristic disclosed below relates to a power supply apparatus provided with an overcurrent protection function, and to an electronic device which is provided with the power supply apparatus.

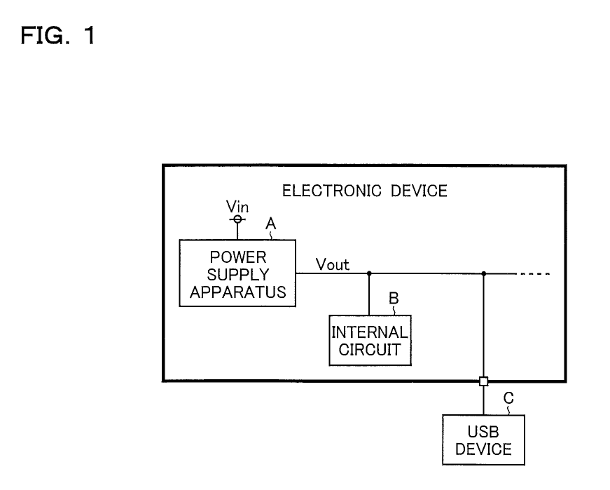

FIG. 1 is a block diagram showing an example of the configuration of an electronic device provided with the power supply according to the present invention. The electronic device (e.g., a notebook PC) of this configuration example has a power supply apparatus A and an internal circuit B, and is also configured so as to enable a Universal Serial Bus (USB) device C to be externally connected.

The power supply apparatus A generates a desired output voltage Vout from an input voltage Vin, and feeds the output voltage Vout to the internal circuit B and/or the externally attached USB device C. The configuration and operation of the power supply apparatus A will be described in detail hereinafter.

The internal circuit B is an electronic circuit (e.g., central processing unit (CPU), chipset, memory, or USB controller) which operates by receiving the fed output voltage Vout from the power supply apparatus A.

The USB device C is an external device which can be detachably attached to a USB port. A self-powered device (printer, scanner, or the like) which operates by receiving a power feed from a commercial power supply, or a bus-powered device (mouse, USB memory, or the like) which operates by receiving a power feed from a power supply apparatus A housed within the electronic device can be connected as the USB device C to the electronic device of the present configuration example.

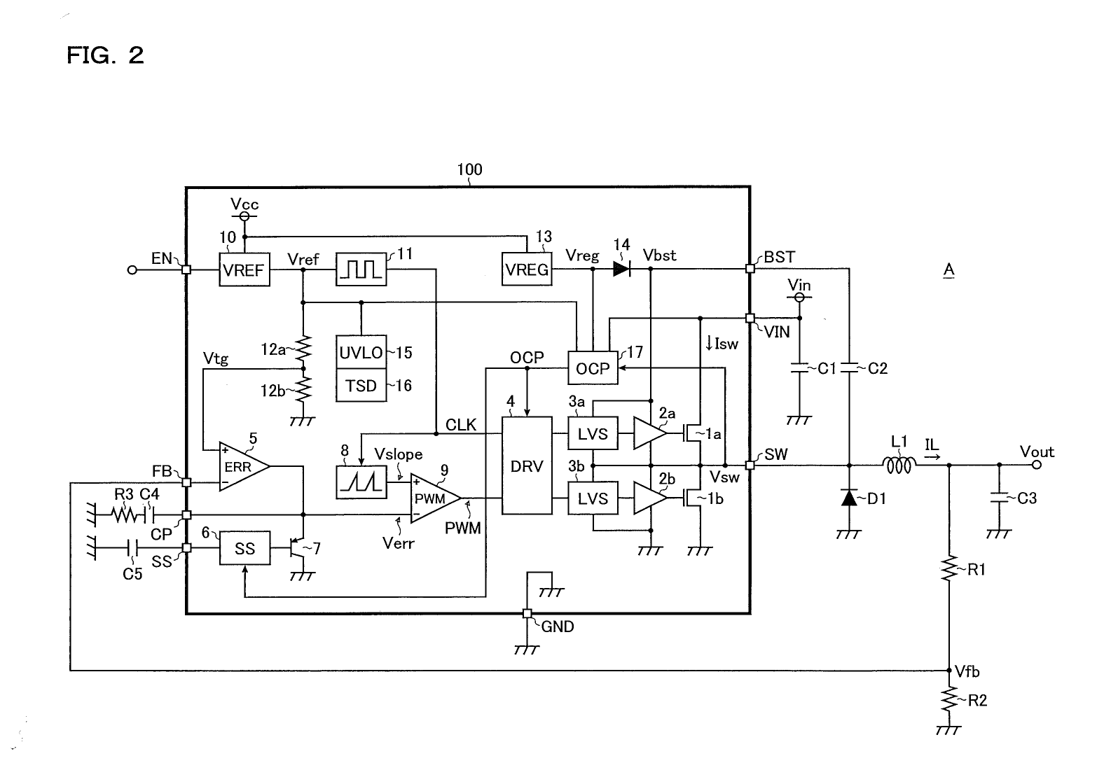

FIG. 2 is a circuit block diagram showing an example of the configuration of the power supply apparatus A.

As shown in FIG. 2, the power supply apparatus A of the present configuration example has a switching power supply IC 100, as well as an externally attached inductor L1, a diode D1, resistors R1 through R3, and capacitors C1 through C5, and is a step-down switching regulator (chopper-type regulator) for generating a desired output voltage Vout from an input voltage Vin.

The switching power supply IC 100 has N-channel MOS field-effect transistors 1a and 1b, drivers 2a and 2b, level shifters 3a and 3b, and a drive control circuit 4, an error amplifier 5, a soft-start control circuit 6, a pnp-type bipolar transistor 7, a slope voltage generation circuit 8, a pulse width modulation (PWM) comparator 9, a reference voltage generation circuit 10, an oscillator 11, resistors 12a and 12b, a boosting constant-voltage generation circuit 13, a diode 14, a under-voltage lockout circuit 15, a thermal shutdown circuit 16, and an overcurrent protection circuit 17.

The switching power supply IC 100 has an enable terminal EN, a feedback terminal FB, a phase compensation terminal CP, a soft-start terminal SS, a bootstrap terminal BST, an input terminal VIN, a switch terminal SW, and a ground terminal GND as means of electrical connection with the outside.

On the outside of the switching power supply IC 100, the input terminal VIN is connected to an application terminal for the input voltage Vin (e.g., 12V), as well as to a ground terminal via the capacitor C1. The switch terminal SW is connected to each of the cathode of the diode D1 and one end of the inductor L1. The anode of the diode D1 is connected to a ground terminal. The other end of the inductor L1 is connected to an outlet terminal for the output voltage Vout, as well as to each of one end of the capacitor C3 and one end of the resistor R1. The other end of the capacitor C3 is connected to a ground terminal. The other end of the resistor R1 is connected to a ground terminal via the resistor R2. The connection node between the resistor R1 and the resistor R2 is connected to the feedback terminal FB as an outlet terminal for the feedback voltage Vfb. The capacitor C2 is connected between the switch terminal SW and the bootstrap terminal BST. The enable terminal EN is a terminal to which an enable signal is applied for controlling whether to drive the switching power supply IC 100. The phase compensation terminal CP is connected to a ground terminal via the capacitor C4 and the resistor R3. The soft-start terminal SS is connected to a ground terminal via the capacitor C5.

The inductor L1, diode D1, and capacitor C3 described above function as a rectification/smoothing circuit for rectifying/smoothing the switch voltage Vsw taken from the switch terminal SW and generating a desired output voltage Vout. The resistors R1, R2 described above function as a feedback voltage generation circuit (resistor divider circuit) for generating a feedback voltage Vfb which corresponds to the output voltage Vout. The capacitor C2 described above forms a bootstrap circuit together with the diode 14 described hereinafter that is housed within the switching power supply IC 100.

The internal configuration of the switching power supply IC 100 will next be described.

The transistors 1a and 1b are a pair of switch elements connected in series between the input terminal VIN (application terminal for the input voltage Vin) and the ground terminal GND, and by driving the switching thereof in complementary fashion, a pulsed switch voltage Vsw is generated from the input voltage Vin. The transistor 1a is a large-sized output transistor (power transistor) for supplying a large switch current Isw, and the transistor 1b is a small-sized synchronous rectification transistor for allowing a ringing noise generated during low load (discontinuous current mode) to flow to the ground terminal GND. Describing the connection relationship of these two elements in further detail, the drain of the transistor 1a is connected to the input terminal VIN. The source and back gate of the transistor 1a are connected to the switch terminal SW. The drain of the transistor 1b is connected to the switch terminal SW. The source and back gate of the transistor 1b are connected to the ground terminal GND.

The term “complementary” used in the present specification refers to cases in which the on/off states of the transistors 1a, 1b are completely reversed, as well as cases in which the on/off transition timing of the transistors 1a, 1b is delayed by a predetermined amount in the interest of through-current prevention.

The drivers 2a and 2b generate a gate voltage (switching drive signal) of the transistors 1a, 1b, respectively, on the basis of the output signals of the level shifters 3a and 3b. An upper power supply terminal of the driver 2a is connected to the bootstrap terminal BST (application terminal for the boost voltage Vbst). A lower power supply terminal of the driver 2a and the upper power supply terminal of the driver 2b are both connected to the switch terminal SW. The lower power supply terminal of the driver 2b is connected to the ground terminal GND. The high level of the gate voltage presented to the transistor 1a is the boost voltage Vbst, and the low level is the ground voltage. The high level of the gate voltage presented to the transistor 1b is the input voltage Vin, and the low level is the ground voltage.

The level shifters 3a and 3b increase the voltage level of the on/off control signal inputted from the drive control circuit 4 and feed the resultant signal to the respective drivers 2a and 2b. The upper power supply terminal of the level shifter 3a is connected to the bootstrap terminal BST (application terminal for the boost voltage Vbst). The lower power supply terminal of the level shifter 3a and the upper power supply terminal of the level shifter 3b are both connected to the switch terminal SW. The lower power supply terminal of the level shifter 3b is connected to the ground terminal GND.

The drive control circuit 4 is a logic circuit for generating an on/off control signal of the transistors 1a, 1b on the basis of a clock signal CLK and a pulse width modulation signal PWM. Specifically, the drive control circuit 4 sets the on/off control signal of the transistor 1a to high level using the rising edge of the clock signal CLK as a trigger, and sets the on/off control signal of the transistor 1a to low level using the rising edge of the pulse width modulation signal PWM as a trigger. The on/off control signal of the transistor 1b is basically the logically inverted signal of the on/off control signal of the transistor 1a.

The error amplifier 5 amplifies the difference between the feedback voltage Vfb and a predetermined target voltage Vtg, and generates an error voltage Verr. As for the connection relationship, the inverting input terminal (−) of the error amplifier 5 is connected to the feedback terminal FB, and the feedback voltage Vfb (corresponding to the actual value of the output voltage Vout) is applied thereto. The non-inverting input terminal (+) of the error amplifier 5 is connected to the connection node of the resistor 12a and the resistor 12b, and the predetermined target voltage Vtg (corresponding to the target setting value of the output voltage Vout) is applied thereto.

The soft-start control circuit 6 initiates startup of the power supply apparatus A as well as charging of the capacitor C5 connected to the soft-start terminal SS, and controls the degree of conduction of the transistor 7, thereby clamping the error voltage Verr to a predetermined soft-start voltage Vss (charging voltage of the capacitor C5+the voltage between the base and emitter of the transistor 7). By such soft-start control, since the output voltage Vout slowly rises while a limit is placed on the current charging the capacitor C3 during startup, it is possible to prevent overshoot of the output voltage Vout and inrush current to the load. When the error voltage Verr has decreased below the soft-start voltage Vss, the transistor 7 is placed in a non-operating state, and soft-start control is therefore ended. The configuration and operation of the soft-start control circuit 6 will be described in detail hereinafter.

The transistor 7 clamps the error voltage Verr to the soft-start voltage Vss during startup of the power supply apparatus A, on the basis of an instruction of the soft-start control circuit 6. Describing the connection relationship specifically, the emitter of the transistor 7 is connected to an output terminal of the error amplifier 5. The collector of the transistor 7 is connected to the ground terminal GND. The base of the transistor 7 is connected to the soft-start terminal SS via the soft-start control circuit 6.

The slope voltage generation circuit 8 generates a slope voltage Vslope having a triangular waveform, a ramp waveform, or a sawtooth waveform on the basis of the clock signal CLK generated by the oscillator 11, and transmits the slope voltage Vslope to the PWM comparator 9.

The PWM comparator 9 compares the error voltage Verr and the slope voltage Vslope, thereby generates a pulse width modulation signal PWM for determining the switching duty, and transmits the pulse width modulation signal PWM to the drive control circuit 4. However, the upper limit of the switching duty is limited to a maximum duty determined within the circuit, and never reaches 100%. Describing the connection relationship specifically, the non-inverting input terminal (+) of the PWM comparator 9 is connected to the output terminal of the slope voltage generation circuit 8. The inverting input terminal (−) of the PWM comparator 9 is connected to the phase compensation terminal CP and to the output terminal of the error amplifier 5.

The reference voltage generation circuit 10 generates a reference voltage Vref (e.g., 4.1 V) from the input voltage Vin and feeds the reference voltage Vref as an internal drive voltage to each component of the switching power supply IC 100.

The oscillator 11 receives the fed reference voltage Vref and generates a rectangular-wave clock signal CLK having a predetermined frequency, and feeds the clock signal CLK to the drive control circuit 4 and the slope voltage generation circuit 8.

The resistors 12a and 12b generate a predetermined target voltage Vtg by dividing the reference voltage Vref, and apply the target voltage Vtg to the non-inverting input terminal (+) of the error amplifier 5. Describing the connection relationship specifically, the resistors 12a and 12b are connected in series between the ground terminal GND and the output terminal (application terminal for the reference voltage Vref) of the reference voltage generation circuit 10, and the connection node of the resistors 12a and 12b is connected to the non-inverting input terminal (+) of the error amplifier 5.

The boosting constant-voltage generation circuit 13 generates a predetermined constant voltage Vreg (e.g., 5 V) from the input voltage Vin.

The diode 14 is connected between the bootstrap terminal BST and the output terminal (output terminal for the constant voltage Vreg) of the boosting constant-voltage generation circuit 13, and is an element which, along with the capacitor C2, constitutes a bootstrap circuit. A desired boost voltage Vbst is taken from the cathode of the diode 14 as a drive voltage for the driver 2a and the level shifter 3a. The boost voltage Vbst has a value higher than the switch voltage Vsw by an amount equal to the charging voltage of the capacitor C2 (voltage obtained by subtracting the forward voltage drop Vf from the constant voltage Vreg).

The under-voltage lockout circuit 15 operates by receiving the fed reference voltage Vref, and is a malfunction protection means for shutting down the switching power supply IC 100 when an abnormal reduction of the input voltage Vin is detected.

The thermal shutdown circuit 16 operates by receiving the fed reference voltage Vref, and is malfunction protection means for shutting down the switching power supply IC 100 when a monitored temperature (junction temperature of the switching power supply IC 100) reaches a predetermined threshold (e.g., 175° C.).

The overcurrent protection circuit 17 operates by receiving the fed reference voltage Vref, monitors the switch current Isw that flows when the output transistor 1a is on, and generates an overcurrent detection signal OCP. The overcurrent detection signal OCP is used as a reset signal for the drive control circuit 4 and the soft-start control circuit 6. Specifically, in the overcurrent protection circuit 17, in the case that the switch current Isw is determined to be in an overcurrent state, the drive control circuit 4 stops the switching operation of the transistors 1a, 1b, and the soft-start control circuit 6 discharges the capacitor C5. This overcurrent protection operation will be described in detail hereinafter.

The bootstrap operation of the power supply apparatus A configured as described above will first be described. When the transistor 1a is switched off and the switch voltage Vsw occurring in the switch terminal SW changes to low level (0 V), a current flows in the path via the diode 14 and the capacitor C2 from the boosting constant-voltage generation circuit 13, and a charge is therefore charged into the capacitor C2 connected between the bootstrap terminal BST and the switch terminal SW. At this time, the boost voltage Vbst (i.e., the charging voltage of the capacitor C2) occurring in the bootstrap terminal BST has the value obtained by subtracting the forward voltage drop Vf of the diode 14 from the constant voltage Vreg (Vreg−Vf).

When the transistor 1a is switched on and the switch voltage Vsw is raised from low level (0 V) to high level (Vin) in the state in which a charge is being charged into the capacitor C2, the boost voltage Vbst is increased to a voltage value (Vin+(Vreg−Vf)) which is higher than the high level (Vin) of the switch voltage Vsw by an amount equal to the charging voltage (Vreg−Vf) of the capacitor C2. Consequently, feeding such a boost voltage Vbst as the drive voltage of the driver 2a and the level shifter 3a enables on/off driving of the transistor 1a.

The output feedback operation of the power supply apparatus A configured as described above will next be described.

In the switching power supply IC 100, the error amplifier 5 amplifies the difference between the feedback voltage Vfb and the target voltage Vtg and generates the error voltage Verr. The PWM comparator 9 compares the error voltage Verr and the slope voltage Vslope and generates the pulse width modulation signal PWM. At this time, the logic of the pulse width modulation signal PWM signal is low level when the error voltage Verr has a higher potential than the slope voltage Vslope, and is high level when the opposite is true. In other words, the higher the potential of the error voltage Verr, the longer the low-level period in one cycle of the pulse width modulation signal PWM, and conversely, the lower the potential of the error voltage Verr, the shorter the low-level period in one cycle of the pulse width modulation signal PWM.

The drive control circuit 4, while preventing the transistors 1a, 1b from being on at the same time, generates the on/off control signal of the transistors 1a, 1b on the basis of the clock signal CLK and the pulse width modulation signal PWM so that the transistor 1a is on and the transistor 1b is off in the low-level period of the pulse width modulation signal PWM, and the transistor 1a is off and the transistor 1b is on in the high-level period of the pulse width modulation signal PWM.

Through the output feedback control described above, switching of the transistor 1a is controlled so that the feedback voltage Vfb matches the target voltage Vtg, or in other words, so that the output voltage Vout matches the desired target setting value.

Since the opening and closing of the transistor 1b is controlled in complementary fashion with respect to the transistor 1a, even when a state occurs in which the switch current Isw is reduced during low load or no load, and ringing noise occurs in the switch voltage Vsw (“discontinuous current mode”), the ringing noise can be allowed to flow to the ground terminal GND through the transistor lb. In other words, when the transistor 1a is off, since the switch voltage Vsw can be reduced to low level (0 V) via the transistor 1b, and the capacitor C2 connected between the bootstrap terminal BST and the switch terminal SW can be adequately charged, the boost voltage Vbst can be reliably increased to the desired voltage level (voltage level higher than the input voltage Vin) at the next on time of the transistor 1a. Accordingly, it is possible to prevent malfunctioning (inability to switch on) of the transistor la, and to realize stable step-down operation.

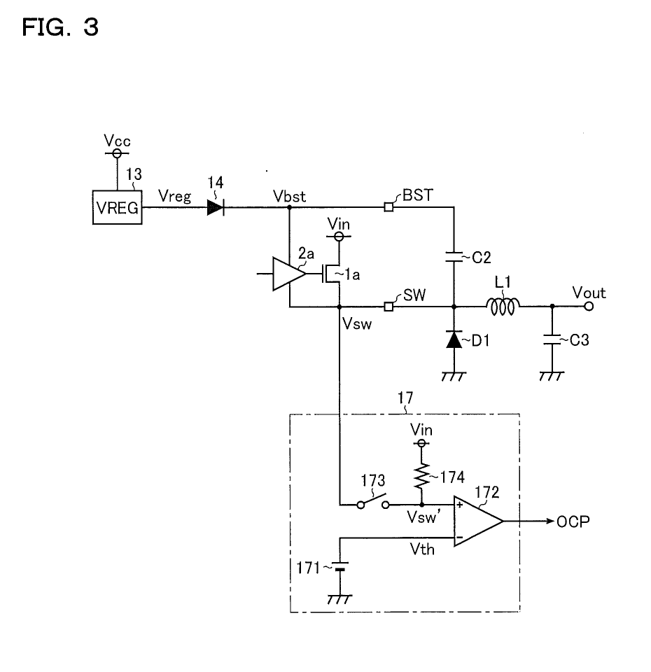

The configuration and basic operation (generation of the overcurrent detection signal OCP) of the overcurrent protection circuit 17 will next be described in detail with reference to FIG. 3.

FIG. 3 is a circuit block diagram showing an example of the configuration of the overcurrent protection circuit 17.

As shown in FIG. 3, the overcurrent protection circuit 17 has a threshold voltage generation unit 171 for generating a threshold voltage Vth; a comparator 172 for comparing the threshold voltage Vth and the switch voltage Vsw taken from one end of the transistor 1a and generating the overcurrent detection signal OCP; a switch 173 connected between the switch terminal SW and the inverting input terminal (−) of the comparator 172 and controlled so as to open and close synchronously with the transistor 1a; and a resistor 174 for pulling up the inverting input terminal (−) of the comparator 172 to the input terminal VIN when the switch 173 is off In the overcurrent protection circuit 17 configured as described above, the switch 173 is switched on when the transistor 1a is switched on, and is switched off when the transistor 1a is switched off. Consequently, the switch voltage Vsw′ applied to the inverting input terminal (−) of the comparator 172 matches the switch voltage Vsw when the transistor 1a is on, and is the input voltage Vin when the transistor 1a is off.

Here, since the switch voltage Vsw obtained when the transistor 1a is on has the value obtained by subtracting the integrated value of the on-resistance Ron of the transistor 1a and the switch current Isw flowing to the transistor 1a from the input voltage Vin (Vin−Ron×Isw), when the on-resistance Ron of the transistor 1a is considered to be constant, the voltage value is lower when the switch current Isw is higher.

Consequently, in the comparator 172, an overcurrent can be detected by comparing the switch voltage Vsw′ applied to the inverting input terminal (−) with the threshold voltage Vth applied to the non-inverting input terminal (+). In the overcurrent protection circuit 17 of the present configuration example, the overcurrent detection signal OCP is low level (logic indicating a normal state) when the switch voltage Vsw′ is higher than the threshold voltage Vth, and the overcurrent detection signal OCP is high level (logic indicating an overcurrent state) when the switch voltage Vsw′ is lower than the threshold voltage Vth.

At the time that the overcurrent detection signal OCP transitions to the logic indicating an overcurrent state (high level), the drive control circuit 4 stops driving the switching of the transistors 1a, 1b, and the switching power supply IC 100 is shut down. The soft-start control circuit 6 also discharges the capacitor C5 in preparation for restarting of the power supply apparatus A.

Through the overcurrent protection circuit 17 configured so as to generate the overcurrent detection signal OCP by comparing the switch voltage Vsw (switch voltage Vsw′) and the threshold voltage Vth, there is no need to insert a sense resistor in the feed path of the output voltage Vout as an overcurrent detection means, and it is therefore possible to reduce cost and enhance output efficiency.

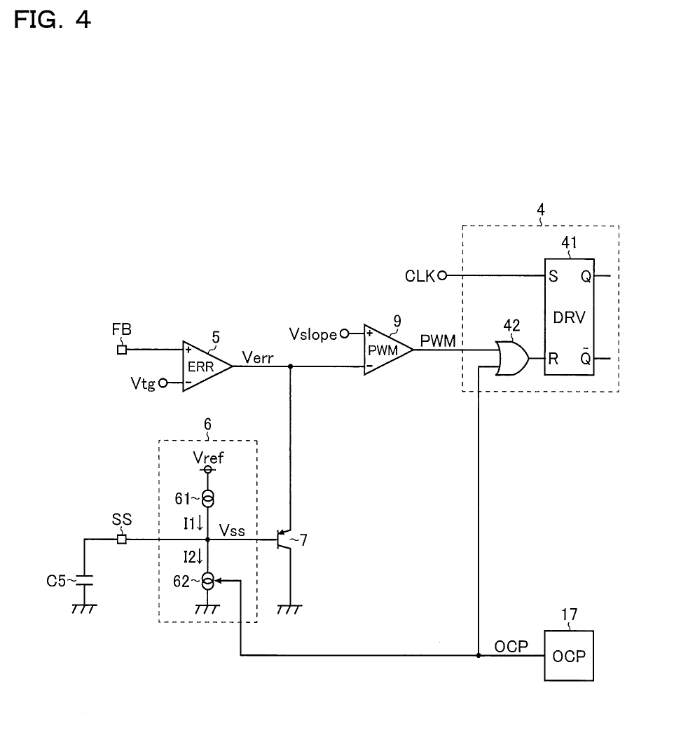

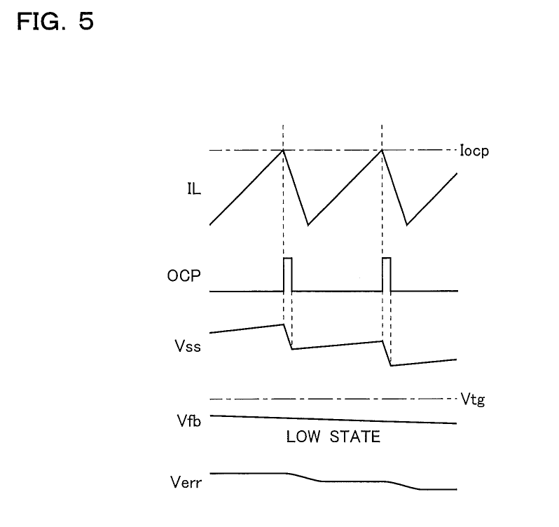

The overcurrent protection operation based on the overcurrent detection signal OCP will next be described in detail with reference to FIGS. 4 and 5. FIG. 4 is a circuit block diagram showing a first configuration example of the drive control circuit 4 and the soft-start control circuit 6. FIG. 5 is a waveform diagram showing the overcurrent protection operation, and shows, in order from the top, the coil current IL, the overcurrent detection signal OCP, the soft-start voltage Vss, the feedback voltage Vfb, and the error voltage Verr. The coil current IL flowing to the coil L1 is shown in FIG. 5 as the current monitored by the overcurrent protection circuit 17, but the overcurrent protection circuit 17 may be configured so as to indirectly monitor the coil current IL by monitoring the switch current Isw (as in the previously described configuration), or may be configured so as to directly monitor the coil current IL (e.g., convert the coil current IL to a voltage signal through use of a sense resistor and compare the voltage signal with a predetermined threshold voltage).

As shown in FIG. 4, the drive control circuit 204 of the first configuration example has an SR flip-flop 41 and a logical sum operator 42.

The set input terminal (S) of the SR flip-flop 41 is connected to an application terminal for the clock signal CLK. The reset input terminal (R) of the SR flip-flop 41 is connected to the output terminal of the logical sum operator 42. The on/off control signals of the transistors 1a, 1b are outputted from the output terminal (Q) and the inverting output terminal (QB), respectively, of the SR flip-flop 41. However, since a predetermined delay must be imposed on the on/off transition timing of the transistors 1a, 1b in the interest of through-current prevention, the abovementioned output signals of the SR flip-flop 41 are transmitted to the respective later-stage level shifters 3a and 3b via a simultaneous-on prevention circuit (not shown).

The first input terminal of the logical sum operator 42 is connected to the output terminal (application terminal for the pulse width modulation signal PWM) of the PWM comparator 9. The second input terminal of the logical sum operator 42 is connected to the output terminal (application terminal for the overcurrent detection signal OCP) of the overcurrent protection circuit 17. Consequently, the logical sum operator 42 feeds the logical sum signal of the pulse width modulation signal PWM and the overcurrent detection signal OCP to the reset input terminal (R) of the SR flip-flop 41 instead of the pulse width modulation signal PWM.

As shown in FIG. 4, the soft-start control circuit 6 of the first configuration example has a constant-current source 61 for generating a charging current I1, and a constant-current source 62 for generating a discharge current I2. A first terminal of the constant-current source 61 is connected to an application terminal for the reference voltage Vref. A second terminal of the constant-current source 61 and a first terminal of the constant-current source 62 are both connected to the capacitor C5 via the soft-start terminal SS, as well as to the base of the transistor 7. A second terminal of the constant-current source 62 is connected to the ground terminal GND. An on/off control terminal of the constant-current source 62 is connected to the output terminal (application terminal for the overcurrent detection signal OCP) of the overcurrent protection circuit 17.

In the power supply apparatus configured as described above, when the coil current IL is detected as having reached a predetermined overcurrent detection value Iocp, the overcurrent protection circuit 17 raises an overcurrent detection signal OCP from low level (normal logical level) to high level (abnormal logical level).

Consequently, when the coil current IL attains an overcurrent state and the overcurrent detection signal OCP is raised to high level (abnormal logical level), the drive control circuit 4 resets the on/off control signal of the transistor 1a to low level irrespective of the pulse width modulation signal PWM. As a result, the transistor 1a is forced off, and the coil current IL is blocked.

When the coil current IL is blocked by the overcurrent protection operation described above, since the overcurrent detection signal OCP falls back to low level (normal logical level), when the clock signal CLK subsequently rises to high level, the drive control circuit 4 sets the on/off control signal of the transistor 1a back to high level, and the transistor 1a is again switched on. However, when the overcurrent state of the coil current IL is not cancelled at that time, the same overcurrent protection operation as described above is commenced, and the transistor 1a is therefore forced off and the coil current IL is again blocked.

In power supply apparatus configured as described above, a “pulse-by-pulse” mode is employed in which a forced reset operation by the overcurrent detection signal OCP and a set operation (self-resetting operation) by the clock signal CLK are repeated as the overcurrent protection operation for the coil current IL.

In the power supply apparatus configured as described above, when the coil current IL attains an overcurrent state and the overcurrent detection signal OCP is raised to high level (abnormal logical level), the constant-current source 62 of the soft-start control circuit 6 is switched on, and the charge accumulated in the capacitor C5 is discharged.

In other words, the power supply apparatus configured as described above is configured so as to simultaneously reset the soft-start control circuit 6 while performing the pulse-by-pulse-mode overcurrent protection operation in the case that the coil current IL attains an overcurrent state.

By adopting such a configuration, since the transistor 1a can be immediately switched off by the pulse-by-pulse-mode overcurrent protection operation at the time that the coil current IL attains a predetermined overcurrent detection value Iocp, the coil current IL does not exceed the overcurrent detection value Iocp, and overcurrent can be suppressed with high effectiveness. At the time the overcurrent state of the coil current IL is cancelled, since the error voltage Verr is clamped to an upper limit value that corresponds to the soft-start voltage Vss (charging voltage of the capacitor C5) even when the output voltage Vout (and the feedback voltage Vfb in accordance thereto) is significantly below the target value thereof, the on-duty of the pulse width modulation signal PWM is suppressed, and the output voltage Vout can be slowly raised. Accordingly, it is possible to eliminate overshoot of the output voltage Vout during return from the overcurrent protection operation.

Consequently, in the power supply apparatus configured as described above, the advantages of both the pulse-by-pulse mode and the soft-start reset mode can be utilized to the maximum degree, while each mode compensates for the disadvantages of the other. It is therefore possible both to reliably suppress overcurrent and to prevent overshoot during return.

The important feature here is not that all of the charge accumulated in the capacitor C5 is immediately discharged during resetting of the soft-start control circuit 6, but that the ratio of the charging current I1 and the discharge current I2 is set so that the soft-start voltage Vss is incrementally reduced and the error voltage Verr is gradually reduced while the pulse-by-pulse-mode overcurrent protection operation is being performed.

As shown in FIG. 5, since the feedback voltage Vfb corresponding to the output voltage Vout is lower than the target voltage Vtg while the pulse-by-pulse-mode overcurrent protection operation is being performed, the error amplifier 5 attempts to output a higher error voltage Verr. However, since the error voltage Verr is clamped to the upper limit value that corresponds to the incrementally reduced soft-start voltage Vss, overshoot of the output voltage Vout can be adequately suppressed even when the overcurrent state of the coil current IL at this time is cancelled, and the switching operation of the transistor 1a is returned.

In case that the coil current IL transiently attains an overcurrent state due to superposition of noise, hot-plugging of the USB device C (external connection of the USB device C in a state in which the power supply to the electronic device is on), or the like, since the overcurrent state is rapidly cancelled, not all of the charge accumulated in the capacitor C5 is discharged, and the soft-start voltage Vss does not decrease completely to zero. Consequently, since soft-start control is not started over from the beginning during return from the overcurrent protection operation, there is no significant decrease of the output voltage Vout, and the electronic device can operate without malfunctioning. As shall be apparent, since the pulse-by-pulse-mode overcurrent protection operation is rapidly implemented even in the case of a transient overcurrent state of the coil current IL, the coil current IL does not exceed the overcurrent detection value Iocp, and overcurrent can be suppressed with high effectiveness.

Since the charge accumulated in the capacitor C5 is completely discharged when the pulse-by-pulse-mode overcurrent protection operation lasts a long time without the overcurrent state of the coil current IL being cancelled, in the case that the overcurrent state of the coil current IL is subsequently cancelled, the same soft-start control is performed as during startup of the power supply apparatus A.

In the embodiment described above, an example is described in which the present invention is applied to a switching regulator for stepping down an input voltage Vin to generate an output voltage Vout, but the present invention is not thus limited, and may be employed in a step-up or step-up/step-down-type output stage.

Various modifications may be added to the configuration of the present invention within the intended scope of the invention, besides the embodiments described above. In other words, the embodiments described above are, in every respect, merely examples, and are not to be considered as limiting. The technical scope of the present invention is defined by the claims, and not by the description of embodiments above, and it shall be apparent that all modifications having equivalent meanings and falling within the scope of the claims are included in the technical scope of the present invention.

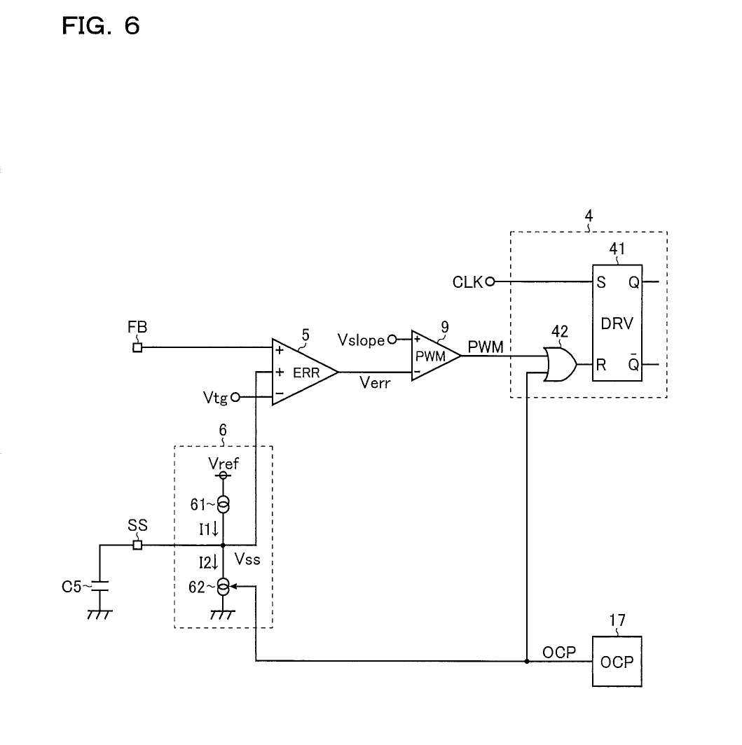

For example, in the embodiments described above, an example is described of a configuration in which the error voltage Verr is clamped to an upper limit value that corresponds to the soft-start voltage Vss, but the present invention is not limited to this configuration; a configuration may be adopted in which the soft-start voltage Vss is inputted to the non-inverting input terminal (+) of the error amplifier 5, and the error amplifier 5 amplifies the difference between the lower of the feedback voltage Vfb and the soft-start voltage Vss, and a predetermined target voltage Vtg, as shown in FIG. 6.

<Second Technical Characteristic>

A second technical characteristic disclosed below relates to a level shifter circuit, and is a technique applied to the level shifters 3a and 3b shown in FIG. 2, for example.

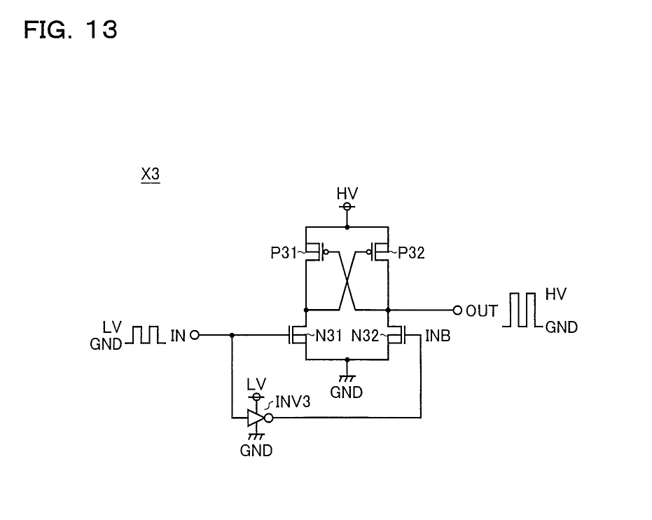

FIG. 13 is a circuit diagram showing a prior art example of a level shifter circuit. The conventional level shifter circuit X3 takes as input an input signal IN which is pulse driven between a first power supply potential LV and a ground potential GND, converts the input signal to an output signal OUT which is pulse-driven between the ground potential GND and a second power supply potential HV higher than the first power supply potential LV, and outputs the output signal; and the level shifter circuit X3 has a first P-channel metal oxide semiconductor (MOS) field-effect transistor P31, a second P-channel MOS field-effect transistor P32, a first N-channel MOS field-effect transistor N31, a second N-channel MOS field-effect transistor N32, and an inverter INV3.

Each of the sources and back gates of the transistors P31, P32 is connected to an application terminal for the second power supply potential HV. The drain of the transistor P31 is connected to the gate of the transistor P32 and the drain of the transistor N31. The drain of the transistor P32 is connected to the gate of the transistor P31, the drain of the transistor N32, and an output terminal for the output signal OUT. The sources and back gates of the transistors N31, N32 are each connected to a ground terminal. The gate of the transistor N31 is connected to an input terminal for the input signal IN. The gate of the transistor N32 is connected to an output terminal of the inverter INV3 (input terminal for an inverted input signal INB). The input terminal of the inverter INV3 is connected to an input terminal for the input signal IN. The positive power supply terminal of the inverter INV3 is connected to an application terminal for the first power supply potential LV. The negative power supply terminal of the inverter INV3 is connected to a ground terminal.

The conventional level shifter circuit X3 has drawbacks in that the greater the difference is between the first power supply potential LV and the second power supply potential HV, the greater the relative range is between the on-resistance value of the transistors P31, P32 and the on-resistance value of the transistors N31, N32, and the logical level of the output signal OUT can no longer be switched to normal.

This problem will be described more specifically, assuming values of 3.3 V for the first power supply potential LV and 10 V for the second power supply potential HV. In this case, when the transistors N31, N32 are switched on, a potential difference of 3.3 V is presented between each gate and source, and when the transistors P31, P32 are switched on, a potential difference of 10 V is presented between each gate and source. In other words, the potential difference applied between each gate and source when the transistors P31, P32 are on is three times the potential difference applied between each gate and source when the transistors N31, N32 are on. Consequently, the on-resistance value of the transistors P31, P32 is small relative to the on-resistance value of the transistors N31, N32.

A case will next be considered in which the input signal IN is raised from low level (ground potential GND) to high level (first power supply potential LV) in a state in which there is a relative range between the on-resistance value of the transistors P31, P32 and the on-resistance value of the transistors N31, N32.

When the input signal IN is low level (ground potential GND), the transistor N31 is placed in the off state, and the transistor N32 is placed in the on state. At this time, the gate potential of the transistor P31 is reduced to low level (ground potential GND) via the transistor N32, and the transistor P31 is therefore placed in the on state. Also at this time, the gate potential of the transistor P32 is increased to high level (second power supply potential HV) via the transistor P31, and the transistor P32 is therefore placed in the off state. As a result, the output signal OUT is placed at low level (ground potential GND).

On the other hand, when the input signal IN is raised from low level (ground potential GND) to high level (first power supply potential LV), the transistor N31 is switched from the off state to the on state, and the transistor N32 is switched from the on state to the off state.

At this time, when the relative range between the on-resistance value of the transistor P31 and the on-resistance value of the transistor N31 is small, since the gate potential of the transistor P32 is reduced from high level (second power supply potential HV) to low level (ground potential GND) via the transistor N31, the transistor P32 is switched from the off state to the on state. Also at this time, the gate potential of the transistor P31 is increased from low level (ground potential GND) to high level (second power supply potential HV) via the transistor P32, and the transistor P31 is therefore switched from the on state to the off state. As a result, the output signal OUT is raised from low level (ground potential GND) to high level (second power supply potential HV).

However, in the case that there is a large relative range between the on-resistance value of the transistor P31 and the on-resistance value of the transistor N31, there is a greater ability to increase the gate potential of the transistor P32 to high level (second power supply potential HV) via the transistor P31 than to reduce the gate potential of the transistor P32 to low level (ground potential GND) via the transistor N31. Therefore, regardless of the fact that the transistor N31 is switched from the off state to the on state, since the gate potential of the transistor P32 can no longer be adequately reduced, it becomes impossible to normally switch the on/off state of the transistor P32. Accordingly, there is a risk of inability to normally switch the logical level of the output signal OUT.

Conversely, when the input signal IN is lowered from high level (first power supply potential LV) to low level (ground potential GND), the relative range between the on-resistance value of the transistor P32 and the on-resistance value of the transistor N32 becomes problematic.

Therefore, in order to correct the relative range between the on-resistance value of the transistors P31, P32 and the on-resistance value of the transistors N31, N32 in the conventional level shifter circuit X3, a configuration is adopted in which the on-resistance value of the transistors N31, N32 is reduced so as to be the same as the on-resistance value of the transistors P31, P32, by designing the transistors N31, N32 so as to have a larger element size than the transistors P31, P32. For example, in the case that the first power supply potential LV is assumed to be 3.3 V and the second power supply potential HV is assumed to be 10 V, the transistors N31, N32 are designed so as to have an element size five times or more larger than the element size of the transistors P31, P32.

However, by this measure, the larger the difference is between the first power supply potential LV and the second power supply potential HV, the greater the degree to which the element size of the transistors N31, N32 must be increased, which hinders efforts to reduce circuit scale.

In the conventional level shifter circuit X3, since it is unavoidable that the transistor P31 and the transistor N31, or the transistor P32 and the transistor N32 are simultaneously on each time the logical level of the input signal IN switches, a through-current intermittently flows from the application terminal for the second power supply potential HV to the ground terminal.

However, the conventional level shifter circuit X3 is configured so as to balance the on-resistance values by reducing the on-resistance value of the transistors N31, N32 to a value equal to the on-resistance value of the transistors P31, P32, as described above. Therefore, an extremely large through-current continues to flow unchecked each time the logical level of the input signal IN switches, thus hindering efforts to reduce power consumption.

Therefore, in view of the abovementioned problems discovered by the present inventors, an object of the second technical characteristic disclosed below is to provide a level shifter circuit whereby the circuit scale and power consumption can both be reduced.

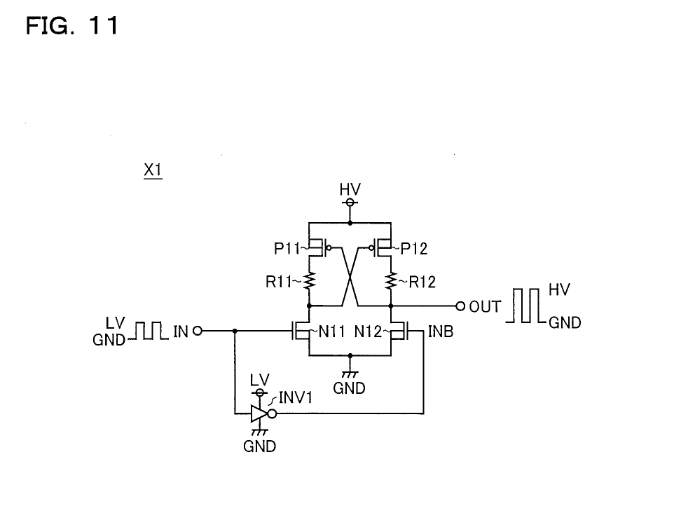

A first embodiment of the level shifter circuit according to the present invention will first be described in detail with reference to FIG. 11. FIG. 11 is a circuit diagram showing a first embodiment of the level shifter circuit according to the present invention. The level shifter circuit X1 of the present embodiment takes as input an input signal IN which is pulse-driven between a first power supply potential LV and a ground potential GND, converts the input signal to an output signal OUT which is pulse-driven between the ground potential GND and a second power supply potential HV higher than the first power supply potential LV, and outputs the output signal; and the level shifter circuit X1 has a first P-channel MOS field-effect transistor P11, a second P-channel MOS field-effect transistor P12, a first N-channel MOS field-effect transistor N11, a second N-channel MOS field-effect transistor N12, an inverter INV1, a first resistor R11, and a second resistor R12.

Each of the sources and back gates of the transistors P11, P12 is connected to an application terminal for the second power supply potential HV. Each of the sources and back gates of the transistors N11, N12 is connected to a ground terminal. The gate of the transistor N11 is connected to an input terminal for the input signal IN. The gate of the transistor N12 is connected to an output terminal of the inverter INV1 (input terminal for an inverted input signal NB). The input terminal of the inverter INV1 is connected to an input terminal for the input signal IN. The positive power supply terminal of the inverter INV1 is connected to an application terminal for the first power supply potential LV. The negative power supply terminal of the inverter INV1 is connected to a ground terminal. One end of the resistor R11 is connected to the drain of the transistor P11. The other end of the resistor R11 is connected to the gate of the transistor P12 and the drain of the transistor N11. One end of the resistor R12 is connected to the drain of the transistor P12. The other end of the resistor R12 is connected to the gate of the transistor P11, the drain of the transistor N12, and an output terminal for the output signal OUT.

In the level shifter circuit X1 configured as described above, when the input signal IN is low level (ground potential GND), the transistor N11 is placed in the off state, and the transistor N12 is placed in the on state. At this time, the gate potential of the transistor P11 is reduced to low level (ground potential GND) via the transistor N12, and the transistor P11 is therefore placed in the on state. Also at this time, the gate potential of the transistor P12 is increased to high level (second power supply potential HV) via the transistor P11, and the transistor P12 is therefore placed in the off state. As a result, the output signal OUT is placed at low level (ground potential GND).

On the other hand, when the input signal IN is raised from low level (ground potential GND) to high level (first power supply potential LV), the transistor N11 is switched from the off state to the on state, and the transistor N12 is switched from the on state to the off state.

At this time, the relative range between the on-resistance value of the transistor P11 and the on-resistance value of the transistor N11 becomes problematic, but in the level shifter circuit X1 of the present embodiment, in order to correct the relative range between the on-resistance value of the transistor P11 and the on-resistance value of the transistor N11, a configuration is adopted in which the resistor R11 (e.g., 10 kΩ) is added to the drain of the transistor P11, and the apparent on-resistance value of the transistor P11 is increased so as to be on par with the on-resistance value of the transistor N11. Such a configuration can be considered to be the exact opposite of the conventional configuration in which the transistor N11 is designed with a larger element size to increase the on-resistance value of the transistor N11 so as to be on par with the on-resistance value of the transistor P11.

By adopting such a configuration, the relative range between the on-resistance value of the transistor P11 and the on-resistance value of the transistor N11 is reduced. Consequently, the gate potential of the transistor P12 is reduced from high level (second power supply potential HV) to low level (ground potential GND) via the transistor N11, and the transistor P12 is therefore switched from the off state to the on state. Also at this time, the gate potential of the transistor P11 is increased from low level (ground potential GND) to high level (second power supply potential HV) via the transistor P12, and the transistor P11 is therefore switched from the on state to the off state. As a result, the output signal OUT is raised from low level (ground potential GND) to high level (second power supply potential HV).

Conversely, when the input signal IN is lowered from high level (first power supply potential LV) to low level (ground potential GND), the relative range between the on-resistance value of the transistor P12 and the on-resistance value of the transistor N12 becomes problematic, but in the level shifter circuit X1 of the present embodiment, a configuration is adopted in which the resistor R12 (e.g., 10 kΩ) is added to the drain of the transistor P12 as means for correcting the relative range between the on-resistance value of the transistor P12 and the on-resistance value of the transistor N12, and the apparent on-resistance value of the transistor P12 is increased so as to be on par with the on-resistance value of the transistor N12.

Such a configuration is advantageous for reducing the circuit scale, because there is no need to increase the element size of the transistors N11, N12 to correct the range between the on-resistance value of the transistors P11, P12 and the on-resistance value of the transistors N11, N12.

In the level shifter circuit X1 of the present embodiment, since it is unavoidable that the transistor P11 and the transistor N11, or the transistor P12 and the transistor N12 are simultaneously on each time the logical level of the input signal IN switches, a through-current intermittently flows from the application terminal for the second power supply potential HV to the ground terminal, the same as in the conventional configuration.

However, the level shifter circuit X1 of the present embodiment is configured so that the on-resistance values are balanced by increasing the apparent on-resistance value of the transistors P11, P12 so as to be on par with the on-resistance value of the transistors N11, N12, as described above. Through-currents can therefore be effectively suppressed, and power consumption can also be reduced.

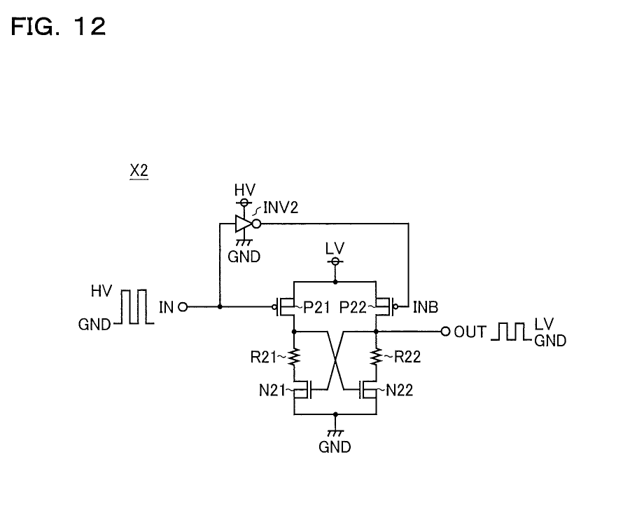

A second embodiment of the level shifter circuit according to the present invention will next be described in detail with reference to FIG. 12. FIG. 12 is a circuit diagram showing a second embodiment of the level shifter circuit according to the present invention. The level shifter circuit X2 of the present embodiment takes as input an input signal IN which is pulse-driven between a second power supply potential HV and a ground potential GND, converts the input signal to an output signal OUT which is pulse-driven between the ground potential GND and a first power supply potential LV lower than the second power supply potential HV, and outputs the output signal; and the level shifter circuit X2 has a first P-channel MOS field-effect transistor P21, a second P-channel MOS field-effect transistor P22, a first N-channel MOS field-effect transistor N21, a second N-channel MOS field-effect transistor N22, an inverter INV2, a first resistor R21, and a second resistor R22.

Each of the sources and back gates of the transistors N21, N22 is connected to a ground terminal Each of the sources and back gates of the transistors P21, P22 is connected to an application terminal for the first power supply potential LV. The gate of the transistor P21 is connected to an input for the input signal IN. The gate of the transistor P22 is connected to an output terminal of the inverter INV2 (input terminal for an inverted input signal INB). The input terminal of the inverter INV2 is connected to an input terminal for the input signal IN. The positive power supply terminal of the inverter INV2 is connected to an application terminal for the second power supply potential HV. The negative power supply terminal of the inverter INV2 is connected to a ground terminal. One end of the resistor R21 is connected to the drain of the transistor N21. The other end of the resistor R21 is connected to the gate of the transistor N22 and the drain of the transistor P21. One end of the resistor R22 is connected to the drain of the transistor N22. The other end of the resistor R22 is connected to the gate of the transistor N21, the drain of the transistor P22, and an output terminal for the output signal OUT.

In the level shifter circuit X2 configured as described above, when the input signal IN is low level (ground potential GND), the transistor P21 is placed in the on state, and the transistor P22 is placed in the off state. At this time, the gate potential of the transistor N22 is increased to high level (first power supply potential LV) via the transistor P21, and the transistor N22 is therefore placed in the on state. Also at this time, the gate potential of the transistor N21 is reduced to low level (ground potential GND) via the transistor N22, and the transistor N21 is therefore placed in the off state. As a result, the output signal OUT is placed at low level (ground potential GND).

On the other hand, when the input signal IN is raised from low level (ground potential GND) to high level (second power supply potential HV), the transistor P21 is switched from the on state to the off state, and the transistor P22 is switched from the off state to the on state.

At this time, the relative range between the on-resistance value of the transistor P22 and the on-resistance value of the transistor N22 becomes problematic, but in the level shifter circuit X2 of the present embodiment, a configuration is adopted in which the resistor R22 (e.g., 10 kΩ) is added to the drain of the transistor N22 as means for correcting the relative range between the on-resistance value of the transistor P22 and the on-resistance value of the transistor N22, and the apparent on-resistance value of the transistor P22 is increased so as to be on par with the on-resistance value of the transistor P22.

By adopting such a configuration, the relative range between the on-resistance value of the transistor P22 and the on-resistance value of the transistor N22 is reduced. Consequently, the gate potential of the transistor N21 is reduced from high level (second power supply potential HV) to low level (ground potential GND) via the transistor P22, and the transistor N21 is therefore switched from the off state to the on state. Also at this time, the gate potential of the transistor N22 is increased from low level (ground potential GND) to high level (second power supply potential HV) via the transistor N21, and the transistor N22 is therefore switched from the on state to the off state. As a result, the output signal OUT is raised from low level (ground potential GND) to high level (second power supply potential HV).

Conversely, when the input signal IN is lowered from high level (second power supply potential HV) to low level (ground potential GND), the relative range between the on-resistance value of the transistor P21 and the on-resistance value of the transistor N21 becomes problematic, but in the level shifter circuit X2 of the present embodiment, a configuration is adopted in which the resistor R21 (e.g., 10 kΩ) is added to the drain of the transistor N21 as means for correcting the relative range between the on-resistance value of the transistor P21 and the on-resistance value of the transistor N21, and the apparent on-resistance value of the transistor N21 is increased so as to be on par with the on-resistance value of the transistor P21.

Such a configuration is advantageous for reducing the circuit scale, because there is no need to increase the element size of the transistors P21, P22 to correct the range between the on-resistance value of the transistors P21, P22 and the on-resistance value of the transistors N21, N22.

In the level shifter circuit X2 of the present embodiment, since it is unavoidable that the transistor P21 and the transistor N21, or the transistor P22 and the transistor N22 are simultaneously on each time the logical level of the input signal IN switches, a through-current intermittently flows from the application terminal for the first power supply potential LV to the ground terminal, the same as in the conventional configuration.

However, the level shifter circuit X2 of the present embodiment is configured so that the on-resistance values are balanced by increasing the apparent on-resistance value of the transistors N21, N22 so as to be on par with the on-resistance value of the transistors P21, P22, as described above. Through-currents can therefore be effectively suppressed, and power consumption can also be reduced.

Various modifications may be added to the configuration of the present invention within the intended scope of the invention, besides the embodiments described above.

<Third Technical Characteristic>

A third technical characteristic disclosed below relates to a threshold voltage generation circuit, to an overcurrent protection circuit which uses the threshold voltage generation circuit, to a switch drive apparatus, and to a power supply apparatus, and is a technique applied to the overcurrent protection circuit 17 shown in FIG. 2, for example.

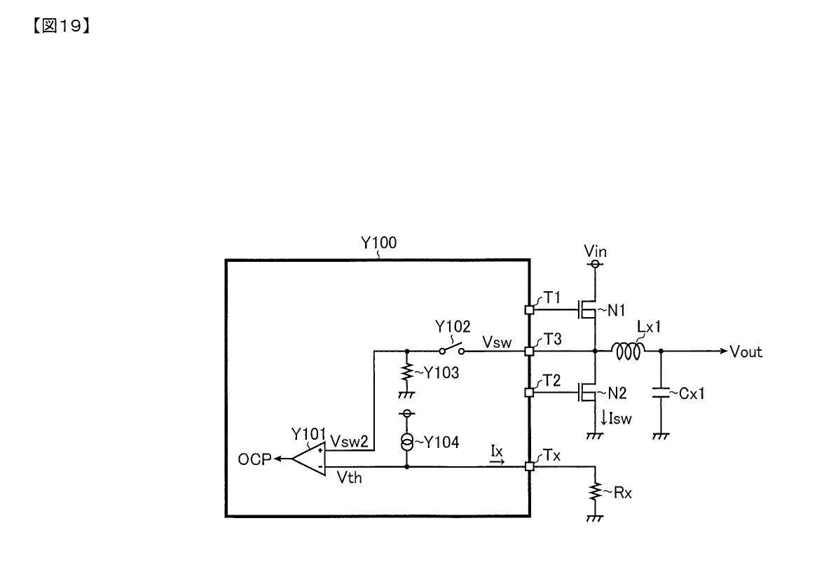

FIG. 19 is a circuit diagram showing a prior art example of the overcurrent protection circuit. The overcurrent protection circuit of the prior art example shown in FIG. 19 is housed within a semiconductor apparatus Y100 (DC/DC controller IC) for functioning as a portion of a synchronous rectification step-down switching regulator, and is configured so as to compare a predetermined threshold voltage Vth and a pulsed switch voltage Vsw taken from the drain of a transistor N2 externally attached to the semiconductor apparatus Y100 (more accurately, a second switch voltage Vsw2 obtained by extracting only the low-level potential of the switch voltage Vsw obtained when the transistor N2 is on), and generate an overcurrent detection signal OCP.

However, as shown in FIG. 19 as well, a threshold voltage generation circuit for generating a predetermined threshold voltage Vth is generally configured so as to generate a desired threshold voltage Vx (=Ix×Rx) by supplying a predetermined constant current Ix to a resistor Rx externally attached to an external terminal Tx. In other words, in the semiconductor apparatus Y100, the need to provide a dedicated external terminal Tx only for externally attaching the resistor Rx for setting the threshold voltage is one factor which hinders efforts to reduce the package size.

Therefore, in view of the abovementioned problems discovered by the present inventors, an object of the third technical characteristic disclosed below is to provide a threshold voltage generation circuit, an overcurrent protection circuit which uses the threshold voltage generation circuit, a switch drive apparatus, and a power supply apparatus whereby the threshold voltage can be arbitrarily set without needlessly increasing the number of external terminal of the semiconductor apparatus.

A configuration to which the present invention is applied will be described in detail below as a threshold voltage generation circuit for arbitrarily setting the overcurrent protection value (threshold voltage Vth) of an overcurrent protection circuit, the threshold voltage generation circuit being housed within a DC/DC controller IC for forming a synchronous rectification step-down switching regulator.

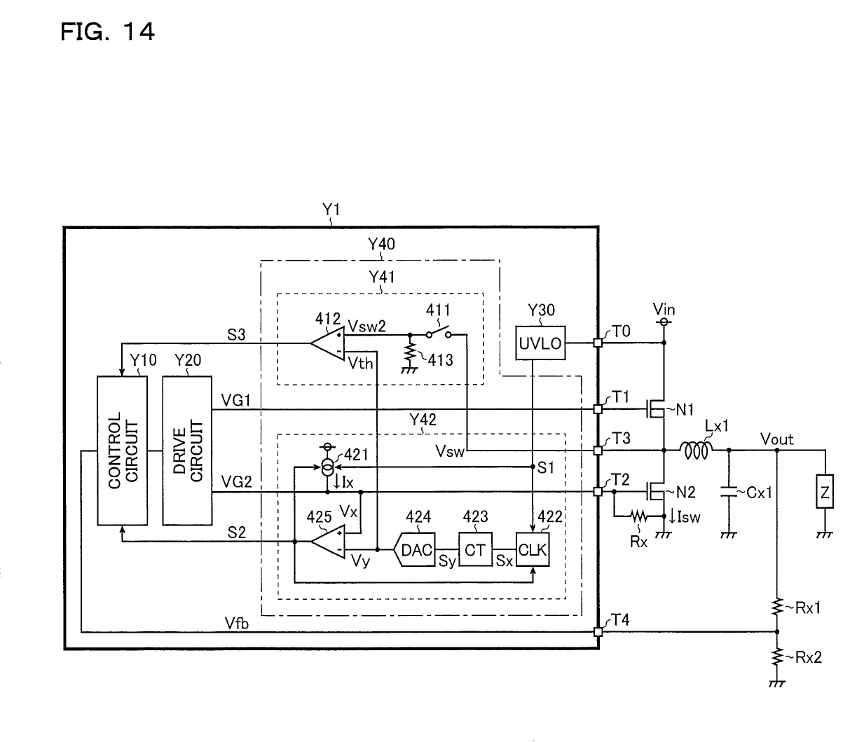

FIG. 14 is a circuit diagram showing an embodiment of the power supply apparatus which uses the threshold voltage generation circuit according to the present invention. The power supply apparatus of the present embodiment has a semiconductor apparatus Y1, as well as an N-channel metal oxide semiconductor (MOS) field-effect transistor N1, an N-channel MOS field-effect transistor N2, a coil Lx1, a capacitor Cx1, a resistor Rx1, a resistor Rx2, and a resistor Rx as discrete elements externally attached to the semiconductor apparatus.

The semiconductor apparatus Y1 has a control circuit Y10, a drive circuit Y20, a under-voltage protection circuit Y30, and an overcurrent protection circuit Y40 as circuit blocks integrated therein, and is a DC/DC controller IC having external terminals T0 through T4 as means of electrical connection with the outside.

On the outside of the semiconductor apparatus Y1, the drain of the transistor N1 is connected to an input terminal for the input voltage Vin. The source and back gate of the transistor N1 are connected to one end of the coil Lx1. The drain of the transistor N2 is connected to one end of the coil Lx1. The source and back gate of the transistor N2 are grounded. The other end of the coil Lx 1 is connected to an output terminal for the output voltage Vout. The output terminal for the output voltage Vout is connected to a load Z. The output terminal for the output voltage Vout is grounded via the capacitor Cx1. The output terminal for the output voltage Vout is also grounded via a resistor divider circuit composed of the resistor Rx1 and the resistor Rx2.

On the outside of the semiconductor apparatus Y1, the external terminal T0 is connected to an input terminal for the input voltage Vin. The external terminal T1 is connected to the gate of the transistor N1. The external terminal T2 is connected to the gate of the transistor N2, and is also connected to a ground terminal via the resistor Rx. The resistor Rx is a pull-down resistor which is externally attached for the purpose of preventing indeterminate logic values at the gate of the transistor N1 at such times as when the semiconductor apparatus Y1 is shut down, but in the overcurrent protection circuit Y40 of the present embodiment, this resistor Rx is diverted for use as a resistor for setting the overcurrent protection value (threshold voltage Vth). The external terminal T3 is connected to one end of the coil Lx1. The external terminal T4 is connected to the connection node between the resistor Rx1 and the resistor Rx2.

The semiconductor apparatus Y1 together with the elements externally attached thereto thus form a synchronous rectification step-down switching regulator for stepping down the input voltage Vin to generate an output voltage Vout, and feeding the output voltage Vout to the load Z.

The control circuit Y10 sends instructions to the drive circuit Y20 to control the driving of the transistor N1 (output switch element) and the transistor N2 (synchronous rectification switch element) on the basis of the feedback voltage Vfb (divided voltage of the output voltage Vout) inputted via the external terminal T4. The control circuit Y10 is also provided with a function for initiating drive control of the transistors N1 and N2 when setting of the overcurrent protection value (threshold voltage Vth) is verified as completed based on a setting completion signal S2 inputted from the overcurrent protection circuit Y40, as well as a function for forcibly stopping the driving of the transistors N1 and N2 when the sink-side switch current Isw flowing to the transistor N2 is verified as being in an overcurrent state on the basis of an overcurrent protection signal S3 also inputted from the overcurrent protection circuit Y40.

The drive circuit Y20 generates drive signals (gate voltages VG1, VG2) of the transistors N1, N2 on the basis of an instruction of the control circuit Y10. The gate voltage VG1 is applied to the gate of the transistor N1 via the external terminal T1, and the gate voltage VG2 is applied to the gate of the transistor N2 via the external terminal T2. When the transistor N1 is on, a gate voltage VG1 higher than the switch voltage Vsw is necessary. In FIG. 14, means for generating such a gate voltage VG1 is not clearly shown, but the desired gate voltage VG1 can be generated through use of a publicly known bootstrap circuit, for example.

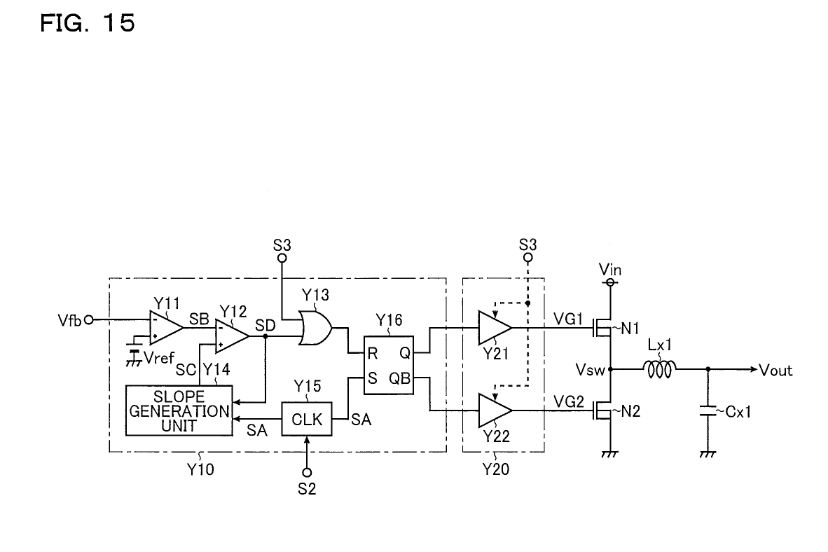

FIG. 15 is a circuit diagram showing an example of the configuration of the control circuit Y10 and the drive circuit Y20. The control circuit Y10 of the present configuration example has an error amplifier Y11, a comparator Y12, a logical sum operator Y13, a slope generation unit Y14, a clock generation unit Y15, and a reset priority RS flip-flop Y16. The drive circuit Y20 has a driver Y21 and a driver Y22.

The non-inverting input terminal (+) of the error amplifier Y11 is connected to an input terminal for the reference voltage Vref. The inverting input terminal (−) of the error amplifier Y11 is connected to an input terminal for the feedback voltage Vfb (divided voltage of the output voltage Vout). The inverting input terminal (−) of the comparator Y12 is connected to the output terminal of the error amplifier Y11. The non-inverting input terminal (+) of the comparator Y12 is connected to the output terminal of the slope generation unit Y14. The first input terminal of the logical sum operator Y13 is connected to an input terminal for the overcurrent protection signal S3 generated by the overcurrent protection circuit Y40. The second input terminal of the logical sum operator Y13 is connected to the output terminal of the comparator Y12. The reset terminal (R) of the RS flip-flop Y16 is connected to the output terminal of the logical sum operator Y13. The set terminal (S) of the RS flip-flop Y16 is connected to the output terminal of the clock generation unit Y15. The output terminal (Q) of the RS flip-flop Y16 is connected to the input terminal of the driver Y21. The output terminal of the driver Y21 is connected to the gate of the transistor N1. The inverting output terminal (QB) of the RS flip-flop Y16 is connected to the input terminal of the driver Y22. The output terminal of the driver Y22 is connected to the gate of the transistor N2.

The error amplifier Y11 amplifies the difference between the feedback voltage Vfb and the reference voltage Vref and generates an error voltage SB. The voltage level of the error voltage SB is higher the lower the output voltage Vout is than the target setting value thereof.

The comparator Y12 compares the error voltage SB and a slope voltage SC and generates a comparison voltage SD. The comparison signal SD is low level when the slope voltage SC is lower than the error voltage SB, and is high level when the slope voltage SC is higher than the error voltage SB.

The logical sum operator Y13 calculates the logical sum of the comparison voltage SD and the overcurrent protection signal S3, and generates a reset signal for the RS flip-flop Y16. The reset signal for the RS flip-flop Y16 is the comparison signal SD as such when the overcurrent protection signal S3 is low level, and when the overcurrent protection signal S3 is high level, the reset signal is always high level, irrespective of the logic of the comparison signal SD. The overcurrent protection signal S3 may be inputted at a stage prior to the RS flip-flop Y16, or may be inputted as the enable signal of the driver Y21 and driver Y22 which form the drive circuit Y20 (as in the configuration indicated by dashed line arrows in FIG. 15).

The slope generation unit Y14 generates a slope voltage SC having a slope waveform (triangular waveform or sawtooth waveform) synchronized with a clock signal SA. Using the rising edge of the clock signal SA as a trigger, the voltage value of the slope voltage SC starts increasing, and using the rising edge of the comparison signal SD as a trigger, the voltage value of the slope voltage SC is reset to zero. However, the resetting of the slope voltage SC by the comparison signal SD is not an essential process; a configuration may be adopted in which the slope voltage SC is reset to zero by the rising edge of the clock signal SA.

The clock generation unit Y15 generates the clock signal SA at a predetermined frequency (e.g., 300 kHz to 1 MHz). The clock generation unit Y15 is also provided with a function for initiating generation of the clock signal SA when setting of the overcurrent protection value (threshold voltage Vth) is verified as completed based on the setting completion signal S2 inputted from the overcurrent protection circuit Y40.

At the rising edge of the set signal (clock signal SA) inputted from the clock generation unit Y15, the RS flip-flop Y16 sets the output signal outputted from the output terminal (Q) to high level and sets the inverting output signal outputted from the inverting output terminal (QB) to low level. At the rising edge of the reset signal inputted from the logical sum operator Y13, the RS flip-flop Y16 resets the output signal outputted from the output terminal (Q) to low level and resets the inverting output signal outputted from the inverting output terminal (QB) to high level.

On the basis of the output signal of the RS flip-flop Y16, the driver Y21 generates the gate voltage VG1 of the transistor N1 and controls the on/off state of the transistor N1. On the basis of the inverting output signal of the RS flip-flop Y16, the driver Y22 generates the gate voltage VG2 of the transistor N2 and controls the on/off state of the transistor N2. Relative on/off control of the transistors N1, N2 is accompanied by generation of the pulsed switch voltage Vsw at the connection node between the source of the transistor N1 and the drain of the transistor N2.

The term “complementary” used in the present specification refers to cases in which the on/off states of the transistors N1, N2 are completely reversed, as well as cases in which the on/off transition timing of the transistors N1, N2 is delayed by a predetermined amount in the interest of through-current prevention.

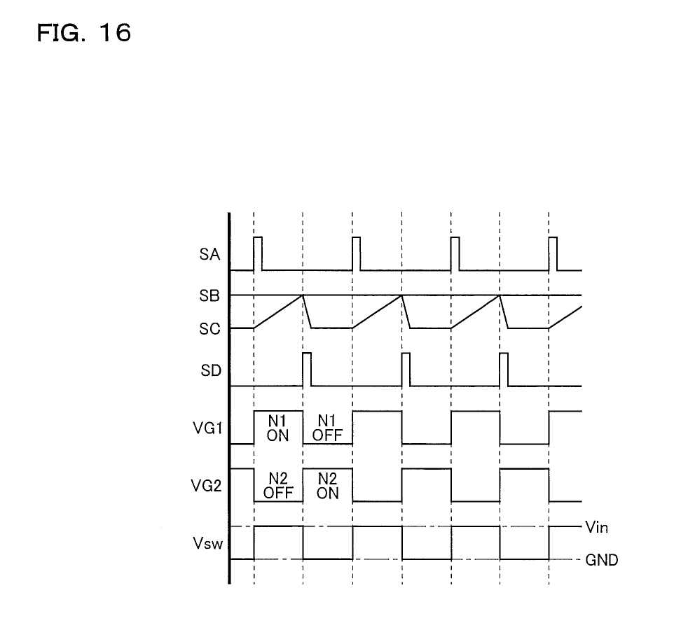

FIG. 16 is a timing chart showing an example of the internal operation of the control circuit Y10 and the drive circuit Y20, and shows, in order from the top, the clock signal SA, the error voltage SB, the slope voltage SC, the comparison voltage SD, the gate voltage VG1, the gate voltage VG2, and the switch voltage Vsw.

As is apparent from FIG. 16, the on-duty (ratio of the high-level period of the gate voltage VG1 with respect to a predetermined pulse width modulation (PWM) cycle determined by the clock signal SA) of the transistor N1 is larger the higher the voltage level of the error voltage SB is, and smaller the lower the voltage level of the error voltage SB is. In other words, the on-duty of the transistor N1 increases the farther the output voltage Vout is from the target value thereof, and decreases the closer the output voltage Vout is to the target value thereof. By such feedback control of the output voltage Vout, the switching of the transistors N1, N2 is controlled so that the feedback voltage Vfb matches the predetermined reference voltage Vref, or in other words, so that the output voltage Vout matches the target value.

The description of the circuit blocks integrated in the semiconductor apparatus Y1 is continued below with reference to FIG. 14.

The under-voltage protection circuit Y30 (under-voltage lockout circuit (UVLO)) compares the input voltage Vin inputted via the external terminal T1 with a predetermined lower limit voltage and generates an under-voltage protection signal S1. Specifically, the under-voltage protection circuit Y30 places the under-voltage protection signal S1 at high level (logical level for canceling the reset state of the semiconductor apparatus Y1) when the input voltage Vin is higher than the predetermined lower limit voltage, and places the under-voltage protection signal S1 at low level (logical level for resetting the semiconductor apparatus Y1) when the input voltage Vin is lower than the predetermined lower limit voltage.

The overcurrent protection circuit Y40 has an overcurrent protection signal generation circuit Y41 for comparing the pulsed switch voltage Vsw taken from the drain of the transistor N2 with the predetermined threshold voltage Vth and generating the overcurrent protection signal S3; and a threshold voltage generation circuit Y42 for generating the threshold voltage Vth at cancellation of resetting of the semiconductor apparatus Y1 (when the power supply is activated).

The overcurrent protection signal generation circuit Y41 has a switch 411, a comparator 412, and a resistor 413. One end of the switch 411 is connected to the drain of the transistor N2 via the external terminal T3. In other words, the switch voltage Vsw is applied to one end of the switch 411. The switch 411 is switched on when the transistor N2 is switched on, and is switched off when the transistor N2 is switched off. The non-inverting input terminal (+) of the comparator 412 is connected to the other end of the switch 411, as well as to a ground terminal via the resistor 413. In other words, the low-level voltage (referred to hereinafter as the second switch voltage Vsw2) of the switch voltage Vsw is applied to the non-inverting input terminal (+) of the comparator 412. The inverting input terminal (−) of the comparator 412 is connected to a threshold voltage output terminal of the threshold voltage generation circuit Y42. In other words, the threshold voltage Vth is applied to the inverting input terminal (−) of the comparator 412.

The threshold voltage generation circuit Y42 has a constant-current source 421, a clock generation unit 422, a counter 423, a digital/analog converter 424 (referred to hereinafter DAC (digital/analog converter) 424), and a comparator 425.

The constant-current source 421 generates a predetermined constant current Ix, and supplies the constant current Ix to the resistor Rx externally attached to the external terminal T2 to cause a predetermined constant voltage Vx (=Ix×Rx) to occur at the external terminal T2. The constant-current source 421 also initiates generation of the constant current Ix when the under-voltage protection operation (rest) of the semiconductor apparatus Y1 is cancelled, on the basis of the under-voltage protection signal S1 generated by the under-voltage protection circuit Y30.

The clock generation unit 422 generates a clock signal Sx having a predetermined frequency. The clock generation unit 422 also initiates generation of the clock signal Sx when the under-voltage protection operation (rest) of the semiconductor apparatus Y1 is cancelled, on the basis of the under-voltage protection signal S1 generated by the under-voltage protection circuit Y30.

The counter 423 counts the number of pulses of the clock signal Sx and outputs the count value as a digital signal Sy.

The DAC 424 converts the digital signal Sy to analog and generates a sweep voltage Vy whose voltage value increases in response to counting up of the counter 423.

The comparator 425 compares the constant voltage Vx inputted to the non-inverting input terminal (+) thereof and the sweep voltage Vy inputted to the inverting input terminal (−) thereof, and generates the setting completion signal S2 for suspending driving of the transistors N1 and N2 and continuing operation of the constant-current source 421 and the clock generation unit 422 until the sweep voltage Vy reaches the constant voltage Vx, and stopping the constant-current source 421 and the clock generation unit 422 and initiating driving of the transistors N1 and N2 once the sweep voltage Vy reaches the constant voltage Vx.

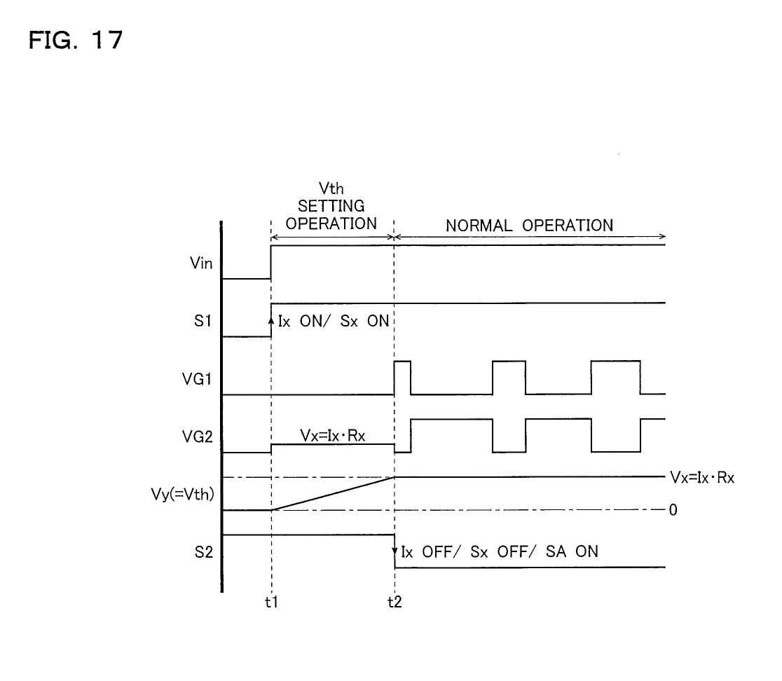

The operation of the threshold voltage generation circuit Y42 configured as described above will next be described in detail with reference to FIG. 17.

FIG. 17 is a timing chart showing the operation whereby the threshold voltage Vth is set by the threshold voltage generation circuit Y42, and shows, in order from the top, the input voltage Vin, the under-voltage protection signal S1, the gate voltage VG1, the gate voltage VG2, the sweep voltage Vy (=threshold voltage Vth), and the setting completion signal S2.

The input voltage Vin rises at time t1, and when the voltage value thereof exceeds a predetermined lower limit voltage, the under-voltage protection signal S1 is raised from low level to high level. The constant-current source 421 and the clock generation unit 422 start operating using the rising edge of the under-voltage protection signal S1 as a trigger.

Specifically, at time t1 and thereafter, the constant-current source 421 supplies the predetermined constant current Ix (e.g., 10 μA) to the resistor Rx externally attached to the external terminal T2, and the predetermined constant voltage Vx (=Ix×Rx) is thereby generated at the external terminal T2. As previously described, the resistor Rx is a pull-down resistor which is externally attached for the purpose of preventing indeterminate logic values at the gate of the transistor N1 at such times as when the semiconductor apparatus 1 is shut down, but the resistance value thereof can be selected with a considerably high degree of freedom (e.g., 1 kΩ to 10 kΩ), and the resistor Rx can be diverted for adequate use as a resistor for setting the overcurrent protection value (threshold voltage Vth). By actively diverting use of the resistor Rx, the number of externally attached elements can be prevented from increasing unnecessarily.

FIG. 17 shows a state in which the constant voltage Vx occurs as the gate voltage VG2 applied to the external terminal T2 from time t1 at which the under-voltage protection signal S1 rises to high level until time t2 at which the sweep voltage Vy reaches the constant voltage Vx.

Since the clock generation unit 422 starts generating the clock signal Sx having a predetermined frequency at time t1, the sweep voltage Vy gradually increases in response to the counting up of the counter 423 for counting the number of pulses of the clock signal Sx.

At time t1 and thereafter, the comparator 425 maintains the setting completion signal S2 at high level so as to suspend driving of the transistors N1 and N2 and continue operation of the constant-current source 421 and the clock generation unit 422 until time t2 at which the sweep voltage Vy reaches the constant voltage Vx. Through such a configuration, since the gate voltage VG2 applied to the external terminal T2 does not fluctuate during the operation for setting the threshold voltage Vth, no malfunction occurs in the operation for setting the threshold voltage Vth even when the external terminal T2 to which the transistor N2 is connected is diverted for use as an external terminal for externally attaching the resistor Rx for setting the threshold voltage.

At time t2, when the sweep voltage Vy reaches the constant voltage Vx, the comparator 425 lowers the setting completion signal S2 from high level to low level so as to stop the constant-current source 421 and clock generation unit 422 and initiate driving of the transistors N1 and N2. The comparator 425 is also configured so as to latch the output when the setting completion signal S2 is lowered from high level to low level.

Through the sequence of operations described above, the count value (digital signal Sy) of the current time is retained in the counter 423, and the voltage value of the sweep voltage Vy obtained by converting the count value to analog is retained by the constant voltage Vx. The threshold voltage generation circuit Y42 then outputs this value to the overcurrent protection signal generation circuit Y41 as the threshold voltage Vth. In other words, the voltage value of the threshold voltage Vth is set to the constant voltage Vx (=Ix×Rx).

As described above, the threshold voltage generation circuit Y42 is configured so that the external terminal T2 to which the transistor N2 is connected is diverted for use as an external terminal for externally attaching the resistor Rx for setting the threshold voltage, rather than using a dedicated external terminal (see the external terminal Tx shown in FIG. 19), and before driving of the transistors N1 and N2 is initiated, the predetermined constant current Ix is supplied from the constant-current source 421 to the resistor Rx externally attached to the external terminal T2. The predetermined constant voltage Vx thereby occurs at the external terminal T2 and is stored as the threshold voltage Vth.

Through such a configuration, since the threshold voltage Vth can be arbitrarily set without needlessly increasing the number of external terminals of the semiconductor apparatus Y1, package size and cost can be reduced.

Since the constant-current source 421 is controlled so as to stop outputting of the constant current Ix before driving of the transistors N1 and N2 is started, no malfunctions are caused in the normal operation of the switching regulator.

In the threshold voltage generation circuit Y42 of the present embodiment, by using the clock generation unit 422, the counter 423, the DAC 424, and the comparator 425, it is possible to scan and store the voltage value of the constant voltage Vx occurring at the external terminal T2 by an extremely simple circuit configuration.

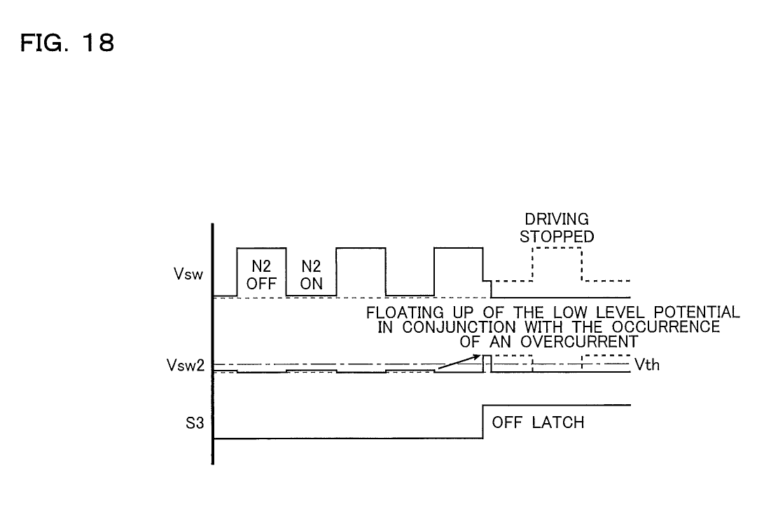

The operation of the overcurrent protection signal generation circuit Y41 configured as described above will next be described in detail with reference to FIG. 18.

FIG. 18 is a timing chart showing an example of the overcurrent protection operation, and shows, in order from the top, the switch voltage Vsw, the second switch voltage Vsw2, and the overcurrent protection signal S3.

As described above, the switch 411 is inserted between the external terminal T3 to which the switch voltage Vsw is inputted and the non-inverting input terminal (+) of the comparator 412, and the switch 411 is switched on when the transistor N2 is switched on, and is switched off when the transistor N2 is switched off. The non-inverting input terminal (+) of the comparator 412 is also pulled down to the ground terminal via the comparator 412. Consequently, the second switch voltage Vsw2 applied to the non-inverting input terminal (+) of the comparator 412 matches the switch voltage Vsw when the transistor N2 is on, and changes to the ground potential GND when the transistor N2 is off.

Since the low-level potential of the switch voltage Vsw obtained when the transistor N2 is on can be computed by the integrated value (=Ron×Isw) of the on-resistance Ron of the transistor N2 and the switch current Isw flowing to the transistor N2, when the on-resistance Ron of the transistor N2 is considered to be constant, the low-level potential of the switch voltage Vsw is higher the greater the switch current Isw is.

Consequently, by using the comparator 412 to compare the second switch voltage Vsw2 and the threshold voltage Vth, it is possible to detect whether the switch current Isw is in an overcurrent state. In the case of the present embodiment, the overcurrent protection signal S3 is low level (logic indicating a normal state) when the second switch voltage Vsw2 is lower than the threshold voltage Vth, and the overcurrent protection signal S3 is high level (logical indicating an overcurrent state) when the second switch voltage Vsw2 is higher than the threshold voltage Vth. The comparator 412 is also configured so as to latch the output when the overcurrent protection signal S3 is raised from low level to high level.

When the overcurrent protection signal S3 is raised from low level to high level, a state occurs in the control circuit Y10 shown in FIG. 15 in which the comparison voltage SD of the comparator Y12 is blocked by the logical sum operator Y13, and the reset state of the RS flip-flop Y16 is maintained. Driving of the transistors N1 and N2 is therefore forcibly stopped. Consequently, since the overcurrent state of the switch current Isw is detected without delay, and the protection operation can be rapidly implemented, damage to the semiconductor apparatus Y1 or peripheral components can be prevented, and the reliability of the set can be increased.

Through the overcurrent protection signal generation circuit Y41 configured as described above, since there is no need to insert a sense resistor in the current path as an overcurrent detection means, it is possible to reduce cost and enhance output efficiency.

Regarding the return from the temporarily latched-off output operation, return can be performed in response to an enable signal or the like from the outside, or a self-return can be performed using a separate internal timer or the like.

In the embodiment described above, an example is described of a configuration in which the present invention is applied as a threshold voltage generation circuit for arbitrarily setting the overcurrent protection value (threshold voltage Vth) of an overcurrent protection circuit, the threshold voltage generation circuit being housed within a DC/DC controller IC for forming a synchronous rectification step-down switching regulator. However, the present invention is not limited to this application, and can be suitably used as means for arbitrarily setting a threshold voltage for use in another application. The present invention can also be broadly applied in diode step-down switching regulators, step-up or step-up/step-down switching regulators, and various other power supply apparatuses.

Various modifications may be added to the configuration of the present invention within the intended scope of the invention, besides the embodiments described above.

For example, in the embodiments described above, a configuration of the threshold voltage generation circuit Y42 is described in which the external terminal T2 to which the transistor N2 is connected is diverted for use as an external terminal for externally attaching the resistor Rx for setting the threshold voltage. However, the present invention is not limited to this configuration; any external element may be diverted for use insofar as the element is a specific external element to which a high-input-impedance element is externally attached, and in which there is no path for flow of the constant current Ix other than the current path via the resistor Rx.

In the embodiments described above, a configuration is described in which a pull-down resistor externally attached between an external terminal and a ground terminal is diverted for use as a resistor for setting the threshold voltage. However, the present invention is not limited to this configuration, and a pull-up resistor externally attached between a specific external terminal and a ground terminal may be used as the resistor for setting the threshold voltage. In this case, a constant-current source may be connected so as to draw a predetermined constant current from a power supply terminal via the pull-up resistor.

### INDUSTRIAL APPLICABILITY

The first technical characteristic (the invention relating to a power supply apparatus provided with an overcurrent protection function, and to an electronic device provided with the power supply apparatus) disclosed in the present specification is a useful technique for increasing the reliability of switching regulators which are widely used as power supply apparatuses in liquid crystal displays, plasma displays, notebook personal computer power supplies (double data rate (DDR)) memory power supplies and the like), Digital Versatile Disc (DVD) players/recorders, Blu-Ray Disc (BD) players, recorders, and the like.

The second technical characteristic (invention relating to a level shifter) disclosed in the present specification is a useful technique for reducing the size and power consumption of level shifter circuits mounted in various electronic devices (liquid crystal displays, plasma displays, optical disk drives, and the like) and used as signal level conversion means.

The third technical characteristic (invention relating to an overcurrent protection circuit) disclosed in the present specification can be suitably used as a technique for arbitrarily adjusting the overcurrent protection values of power supply apparatuses mounted in various electronic devices (liquid crystal displays, plasma displays, optical disk drives, and the like), for example.

### LIST OF REFERENCE SIGNS

A power supply apparatus (switching regulator)
B internal circuit
C USB device
100 switching power supply IC
1a N-channel MOS field-effect transistor (for output)
1b N-channel MOS field-effect transistor (for ringing noise discharge)
2a, 2b drivers
3a, 3b level shifters
4 drive control circuit
41 SR flip-flop
42 logical sum operator
5 error amplifier
6 soft-start control circuit
61 constant-current source (for charging)
62 constant-current source (for discharging)
7 pnp-type bipolar transistor
8 slope voltage generation circuit
9 PWM comparator
10 reference voltage generation circuit
11 oscillator
12a, 12b resistors
13 boosting constant-voltage generation circuit
14 diode
15 under-voltage lockout circuit
16 thermal shutdown circuit
17 overcurrent protection circuit
171 threshold voltage generation unit
172 comparator
173 switch
174 resistor
L1 inductor
D1 diode
R1 through R3 resistors
C1 through C5 capacitors
EN enable terminal
FB feedback terminal
CP phase compensation terminal
SS soft-start terminal
BST bootstrap terminal
VIN input voltage
SW switch terminal
GND ground terminal
X1, X2 level shifter circuits
P11, P21 first P-channel MOS field-effect transistors
P12, P22 second P-channel MOS field-effect transistors
N11, N21 first N-channel MOS field-effect transistors
N12, N22 second N-channel MOS field-effect transistors
INV1, INV2 inverters
R11, R21 first resistors
R12, R22 second resistors
LV first power supply potential
HV second power supply potential
GND ground potential
IN input signal
INB inverted input signal
OUT output signal
Y1 semiconductor apparatus (DC/DC controller IC)
Y10 control circuit
Y11 error amplifier
Y12 comparator
Y13 logical sum operator
Y14 slope generation unit
Y15 clock generation unit
Y16 RS flip-flop
Y20 drive circuit
Y21, Y22 drivers
Y30 under-voltage protection circuit (UVLO circuit)
Y40 overcurrent protection circuit
Y41 overcurrent protection signal generation circuit
411 switch
412 comparator
413 resistor
Y42 threshold voltage generation circuit
421 constant-current source
422 clock generation unit
423 counter
424 digital/analog converter (DAC)
425 comparator
N1 N-channel MOS field-effect transistor (switch element for output)
N2 N-channel MOS field-effect transistor (switch element for synchronous rectification)
Lx1 coil
Cx1 capacitor
Rx1, Rx2 resistors
Rx resistor (for pull-down/for setting protection value)
T0 through T4 external terminals
Z load
Vin input voltage
Vout output voltage
Vsw switch voltage
Vsw2 second switch voltage
Isw switch current (sink side)
Ix constant current (for setting protection value)
Vx constant voltage (for setting protection value)
Vy sweep voltage
Sx clock signal (for counter increment)
Sy digital signal (counter value)
S1 under-voltage protection signal
S2 setting completion signal
S3 overcurrent protection signal
VG1, VG2 gate voltages
SA clock signal (for setting PWM cycle)
SB error voltage
SC slope voltage
SD comparison voltage

1. A power supply apparatus for generating a desired output voltage from an input voltage by switching an output transistor on and off and driving a coil current; said power supply apparatus comprising:
a drive control circuit for generating an on/off control signal of said output transistor;
an overcurrent protection circuit for directly or indirectly monitoring said coil current and generating an overcurrent detection signal; and
a soft-start control circuit for suppressing a rise in said output voltage by using a soft-start voltage for starting an increase slowly after startup of said power supply apparatus, wherein
when said coil current is in an overcurrent state,
said drive control circuit repeats a forced reset operation of said on/off control signal in accordance with said overcurrent detection signal, and a set operation of said on/off control signal in accordance with a clock signal of a predetermined frequency, as a pulse-by-pulse overcurrent protection operation; and
said soft-start control circuit gradually reduces said soft-start voltage as a reset operation in accordance with said overcurrent detection signal.

2. The power supply apparatus according to claim 1, wherein
said soft-start control circuit includes a capacitor; a first constant-current source for generating a charging current for said capacitor; and a second constant-current source for generating a discharge current for said capacitor in accordance with said overcurrent detection signal; and
the ratio of said charging current and said discharge current is set so that during a reset operation in accordance with said overcurrent detection signal, not all of the charge accumulated in said capacitor is immediately discharged, and said soft-start voltage is lowered in stages while said overcurrent protection operation of a pulse-by-pulse mode is being performed.

3. The power supply apparatus according to claim 2, further comprising:
an error amplifier for amplifying the difference between a predetermined target voltage and a feedback voltage which corresponds to said output voltage and generating an error voltage;
an oscillator for generating said clock signal and transmitting the clock signal as a setting signal of said drive control circuit;
a slope voltage generation circuit for generating a slope voltage having a triangular waveform, a ramp waveform, or a sawtooth waveform on the basis of said clock signal; and
a PWM comparator for comparing said error voltage and said slope voltage to generate a pulse width modulation signal, and transmitting the pulse width modulation signal as a reset signal of said drive control circuit.

4. The power supply apparatus according to claim 3, comprising a clamp circuit for clamping said error voltage to an upper limit value which corresponds to said soft-start voltage.

5. The power supply apparatus according to claim 3, wherein said error amplifier amplifies the difference between said target voltage and the lower of said feedback voltage and said soft-start voltage and generates said error voltage.

6. An electronic device comprising the power supply apparatus according to claim 1.

7. The electronic device according to claim 6, comprising a port to which is mounted a bus power device which operates upon receiving a power feed from said power supply apparatus.

8. The power supply apparatus according to claim 1, further comprising a level shifter circuit inserted between said drive control circuit and said output transistor.

9. The power supply apparatus according to claim 8, wherein
said level shifter circuit receives as input an input signal which is pulse-driven between a first power supply potential and a ground potential, converts the input signal to an output signal which is pulse-driven between the ground potential and a second power supply potential higher than the first power supply potential, and outputs the output signal;
and wherein the level shifter circuit includes:
first and second P-channel field-effect transistors, each of the sources thereof being connected to an application terminal for the second power supply potential;
first and second N-channel field-effect transistors, each of the sources thereof being connected to a ground terminal, and each of the gates thereof being connected to an input terminal for said input signal and a logically inverted signal thereof;
a first resistor, one end thereof being connected to the drain of the first P-channel field-effect transistor and another end being connected to the gate of the second P-channel field-effect transistor and the drain of the first N-channel field-effect transistor; and
a second resistor, one end thereof being connected to the drain of the second P-channel field-effect transistor and another end being connected to the gate of the first P-channel field-effect transistor, the drain of the second N-channel field-effect transistor, and an output terminal of said output signal.

10. The power supply apparatus according to claim 8, wherein
said level shifter circuit receives as input an input signal which is pulse-driven between a second power supply potential and a ground potential, converts the input signal to an output signal which is pulse-driven between the ground potential and a first power supply potential lower than the second power supply potential, and outputs the output signal;
and wherein the level shifter circuit includes:
first and second N-channel field-effect transistors, each of the sources thereof being connected to a ground terminal;
first and second P-channel field-effect transistors, each of the sources thereof being connected to an application terminal for the first power supply potential, and each of the gates thereof being connected to an input terminal for said input signal and a logically inverted signal thereof;
a first resistor, one end thereof being connected to the drain of the first N-channel field-effect transistor and another end being connected to the gate of the second N-channel field-effect transistor and the drain of the first P-channel field-effect transistor; and
a second resistor, one end thereof being connected to the drain of the second N-channel field-effect transistor and another end being connected to the gate of the first N-channel field-effect transistor, the drain of the second P-channel field-effect transistor, and an output terminal of said output signal.

11. A threshold voltage generation circuit integrated in a semiconductor apparatus; wherein the threshold voltage generation circuit is configured for:
diverting a specific external terminal, to which a high-input-impedance element is externally attached, for use as an external terminal for externally attaching a resistor for setting a threshold voltage;
causing a predetermined constant voltage to occur in said specific external terminal by supplying a predetermined constant current to said specific external terminal prior to the start of normal operation of said semiconductor apparatus; and
storing the constant voltage as the threshold voltage.

12. The threshold voltage generation circuit according to claim 11, comprising:
a constant-current source for supplying said constant current to said specific external terminal;
a clock generation unit for generating a clock signal;
a counter for counting the number of pulses of said clock signal and outputting the count value as a digital signal;
a digital/analog converter for converting said digital signal to analog and generating a sweep voltage in which the voltage value increases in accordance with counting up performed by said counter; and
a comparator for comparing said sweep voltage and said constant voltage and generating a control signal for suspending normal operation of said semiconductor apparatus and causing said constant-current source and said clock generation unit to operate until said sweep voltage reaches said constant voltage, then stopping said constant-current source and said clock generation unit and initiating normal operation of said semiconductor apparatus once said sweep voltage has reached said constant voltage; wherein
said sweep voltage is outputted as said threshold voltage.

13. The threshold voltage generation circuit according to claim 12, wherein operation of said constant-current source and said clock generation unit is initiated when an under-voltage protection operation of said semiconductor apparatus is cancelled.

14. The threshold voltage generation circuit according to claim 11 wherein a pull-up resistor or pull-down resistor externally attached to said specific external terminal is diverted for use as said resistor for setting the threshold voltage.

15. An overcurrent protection circuit comprising:
the threshold voltage generation circuit according to claim 11; and
an overcurrent protection signal generation circuit for comparing said threshold voltage and a pulsed switch voltage which is drawn from one end of a switch element externally attached to said semiconductor apparatus, and generating an overcurrent protection signal.

16. The overcurrent protection circuit according to claim 15, wherein said high-input-impedance element is a field-effect transistor used as said switch element.

17. A switch drive apparatus integrated in a semiconductor apparatus, the switch drive apparatus comprising:
a control circuit for controlling the driving of said switch element;
a drive circuit for generating a drive signal of said switch element on the basis of an instruction of said control circuit; and
the overcurrent protection circuit according to claim 15; said switch drive apparatus characterized in that
at least one of said control circuit and said drive circuit stops the driving of said switch element when a switch current flowing to said switch element is recognized as being in an overcurrent state on the basis of said overcurrent protection signal.

18. A power supply apparatus comprising:
the switch drive apparatus according to claim 17;
said switch element, switched on and off by said switch drive apparatus; and
a smoothing circuit for smoothing said switch voltage and generating an output voltage.

19. A level shifter circuit for receiving as input an input signal which is pulse-driven between a first power supply potential and a ground potential, converting the input signal to an output signal which is pulse-driven between the ground potential and a second power supply potential higher than the first power supply potential, and outputting the output signal; said level shifter comprising:
first and second P-channel field-effect transistors, each of the sources thereof being connected to an application terminal for the second power supply potential;
first and second N-channel field-effect transistors, each of the sources thereof being connected to a ground terminal, and each of the gates thereof being connected to an input terminal for said input signal and a logically inverted signal thereof;
a first resistor, one end thereof being connected to the drain of the first P-channel field-effect transistor and another end being connected to the gate of the second P-channel field-effect transistor and the drain of the first N-channel field-effect transistor; and
a second resistor, one end thereof being connected to the drain of the second P-channel field-effect transistor and another end being connected to the gate of the first P-channel field-effect transistor, the drain of the second N-channel field-effect transistor, and an output terminal of said output signal.

20. A level shifter circuit for receiving as input an input signal which is pulse-driven between a second power supply potential and a ground potential, converting the input signal to an output signal which is pulse-driven between the ground potential and a first power supply potential lower than the second power supply potential, and outputting the output signal; said level shifter circuit comprising:
first and second N-channel field-effect transistors, each of the sources thereof being connected to ground terminal;
first and second P-channel field-effect transistors, each of the sources thereof being connected to an application terminal for the first power supply potential, and each of the gates thereof connected to an input terminal for said input signal and a logically inverted signal thereof;
a first resistor, one end thereof being connected to the drain of the first N-channel field-effect transistor and another end being connected to the gate of the second N-channel field-effect transistor and the drain of the first P-channel field-effect transistor; and
a second resistor, one end thereof being connected to the drain of the second N-channel field-effect transistor and another end being connected to the gate of the first N-channel field-effect transistor, the drain of the second P-channel field-effect transistor, and an output terminal of said output signal.
